(19) United States
(12) Patent Application Publication
(10) Pub. No.: US 2026/0370283 A1
(43) Pub. Date: Nov. 19, 2026

(54) METHODS FOR IMPLICIT CSI FEEDBACK WITH RANK GREATER THAN ONE

(71) Applicant: Telefonaktiebolaget LM Ericsson (PUBL), Stockholm (SE)

(72) Inventors: Chandan PRADHAN, Minami Ward City, Kanagawa (JP); Ilmiawan SHUBHI, MALMÖ (SE); Emil RINGH, SOLNA (SE); Adrian GARCIA RODRIGUEZ, PARIS (FR); Mårten SUNDBERG, Årsta (SE)

(21) Appl. No.: 19/126,286

(22) PCT Filed: Oct. 25, 2023
(86) PCT No.: PCT/SE2023/051052

§ 371 Date: May 1, 2025

(30) Foreign Application Priority Data
Nov. 4, 2022 (EP) 22306671.3

(51) Int. Cl. H04B 7/06; H04B 7/0413

(52) U.S. Cl. CPC H04B 7/0626; H04B 7/0413

(57) ABSTRACT

According to an aspect, there is provided method performed by a user equipment, UE. The method comprises using (2901) an encoder of an autoencoder to compress multiple input multiple output, MIMO, channel state information, CSI, for a channel between the UE and a base station; forming (2902) a CSI report using a mapping between quantised bits representing the compressed MIMO CSI and layers of the channel. The mapping is dependent on an estimated rank for the channel and/or a layer order. The method further comprises sending (2903), to the base station, the CSI report and a rank indication for the estimated rank.

### TECHNICAL FIELD

This disclosure relates to the communication of channel state information (CSI) from a User Equipment (UE) to a base station (e.g. a Next Generation (NG) NodeB (gNB)).

### BACKGROUND

The 5^{th} generation (5G) mobile wireless communication system (known as New Radio—NR) uses Orthogonal Frequency Division Multiplexing (OFDM) with configurable bandwidths and subcarrier spacing to efficiently support a diverse set of use cases and deployment scenarios. With respect to Long Term Evolution (LTE), NR improves in deployment flexibility, user throughputs, latency and reliability. With NR comes also enhanced support for spatial multiplexing in which time-frequency resources are spatially shared across users, commonly referred to as Multi-User Multiple Input Multiple Output (MIMO) (MU-MIMO).

MU-MIMO operations is illustrated in FIG. 1 where a multi-antenna base station with N_{TX} antenna ports is spatially transmitting information to several UEs, in which sequence S⁽¹⁾ is aimed for UE(1), S⁽²⁾ is aimed for UE(2), etc. Before modulation and transmission, precoding

$${W}_{V}^{( j )}$$

is applied to each sequence to spatially separate the transmissions, i.e., to mitigate multiplexing interference.

At receiver sides, each UE demodulates its received signal and combines receive antenna signals to obtain an estimate Ŝ⁽ⁱ⁾ of transmitted sequence. This estimate Ŝ⁽ⁱ⁾ can be expressed as

$${\hat{S}}^{( i )} = {\underbrace{{W}_{U}^{( i )} {H}^{( i )} {W}_{V}^{( i )}}}_{\approx I} {S}^{( i )} + {W}_{U}^{( i )} {H}^{( i )} {\sum }_{j , j \neq i} {W}_{V}^{( j )} {S}^{( j )} ,$$

where the second term represents the spatial multiplexing interference seen by UE(i). The goal for the base station is to construct the set of precoders

$$\{ {W}_{V}^{( j )} \}$$

such that the norm

$$‖ {H}^{( i )} {W}_{V}^{( i )} ‖$$

is large whereas the norm

$$‖ {H}^{( j )} {W}_{V}^{( i )} ‖ ,$$

j≠i is small. In other words, the precoder

$${W}_{V}^{( i )}$$

shall correlate well with the channel H⁽ⁱ⁾ observed by UE(i) whereas it shall correlate poorly with other channels.

To construct precoders for efficient MU-MIMO transmissions, the base station needs to acquire detailed knowledge of the channels H(i). In deployments where channel reciprocity holds, channel knowledge can be acquired from sounding reference signals (SRS) that are transmitted periodically, or on demand, by active UEs. Based on these SRS, the base station estimates H⁽ⁱ⁾. However, when channel reciprocity does not hold or when SRS coverage is limited, active UEs need to feedback channel details to the base station. In NR (as well as in LTE), this is done by having the base station to periodically transmit Channel State Information reference signals (CSI-RS) from which a UE can estimate its channel. The UE then reports CSI from which the base station can determine suitable precoders for MU-MIMO.

The CSI feedback mechanism targeting MU-MIMO operations in NR is referred to as CSI type II, in which a UE reports CSI feedback with high CSI resolution (Reference [1]). It is based on specifying sets of Discrete Fourier Transform (DFT) base functions (grid of beams) from which the UE selects those that best match its channel conditions (like classical codebook Precoder Matrix Indicator (PMI)). The number of beams the UE reports is configurable via Radio Resource Control (RRC) signaling, and may be 2 or 4 for Rel-15 Type II or 2, 4 or 6 for Rel-16 Type II. In Rel-16 Type II, the CSI report can be further compressed in the frequency domain (FD), where a set of FD DFT basis vectors are selected by the UE. The number of selected FD basis vectors is a function of the number of Channel Quality information (CQI) subbands, the number of PMI subbands per CQI subband and a ratio that determines the FD compression (termed as pᵥ in Reference [1], where v is the layer index), which is configured by gNB via RRC signaling. In addition, the UE also reports non-zero coefficients (NZCs) associated with the selected beams for Rel-15 Type II, which informs the gNB how these beams should be combined in terms of relative amplitude scaling and co-phasing for each subband. In Rel-16, the reported NZCs are then associated with selected beams and FD basis vectors. In Rel-16, to further compress the CSI report, gNB also configures a ratio, termed as β, to the UE via RRC signaling, that determines the maximum number of NZCs to be reported. For example, for a single layer transmission where 2L beams and M FD basis vectors are configured by gNB, there are in total 2LM linear combination coefficients. Then, only [2LMβ] NZCs will be reported at most, the remaining 2LM−[2LMβ] are treated as zeros and are not reported. The selected beams are commonly used for all subbands and all transmission layers, whereas the NZCs (for both Rel-15 and Rel-16 Type II) and FD basis vectors (for Rel-16 Type II) are layer-specific.

To further explain the structure of the Type II CSI, and example of the Rel-15 CSI type II feedback is illustrated in FIG. 2, from which it can be observed that the selection of DFT beam vectors bn, and their relative amplitudes an, are determined from a wideband perspective whereas the co-phasing is per subband. Here, wideband means that the selected DFT beam vectors are the same for all subcarriers used in the OFDM transmission, whereas subband means that co-phasing parameters are determined over subsets of contiguous subcarriers. The co-phasing parameters are quantized such that e^{jθ}^{ₙ} is taken from either a Quadrature Phase Shift Keying (QPSK) or 8 Phase Shift Keying (8PSK) signal constellation.

With k denoting a sub-band index, the precoder reported by the UE can be expressed as

$${W}_{V} [ k ] = {\sum }_{n} {b}_{n} {a}_{n} {e}^{j {θ}_{n} [ k ]} .$$

Note that the reporting overhead for Type II CSI is generally large, especially when comparing to the Type I CSI. A dominant part of the reporting overhead is from subband reporting, e.g., the layer-specific NZCs. For instance, it requires about 7 bits (the actual number depends on the release version and parameter configuration) to report the phase and amplitude for one coefficient.

Autoencoders for Artificial Intelligence (AI)/Machine Learning (ML)-enhanced CSI reporting—Recently neural network based autoencoders (AEs) have shown promising results for compressing downlink MIMO channel estimates for uplink (UL) feedback. For example, Zhilin Lu et al, arXiv, 2105.00354 v1, 2021 (Reference [2]) provides a recent summary of academic work. AEs can be used to improve the accuracy of reported CSI from the UE to the network (NW).

Furthermore, the 3^{rd} Generation Partnership Project (3GPP) decided to start a study item for Rel.18 that includes the use case of AI-based CSI reporting in which AEs will play a central part of the study (References [3] and [4]). Specifically, an AE is a type of artificial neural network (NN) that can be used to compress and decompress data, in an unsupervised manner, often with high fidelity.

FIG. 3 illustrates a simple fully connected (dense) AE. The AE is divided into two parts:
an encoder (used to compress the input data X), and
a decoder (used to de-compress the input data).

AEs can have different architectures. For example, AEs can be based on dense NNs, multi-dimensional convolution NNs, variational, recurrent NNs, transformer networks, or any combination thereof. However, all AE architectures possess an encoder-bottleneck-decoder structure illustrated in FIG. 3.

The size of the codeword (denoted by Y in FIG. 3) of an AE is typically a lot smaller than the size of the input data (X in FIG. 3). The AE encoder thus reduces the dimensionality of the input features X down to Y. The decoder part of the AE tries to invert the encoder and reconstruct X with minimal error, according to some predefined loss function.

FIG. 4 illustrates how an AE might be used for AI/ML-enhanced CSI reporting in NR. The UE measures the channel in the downlink using CSI-RS. The UE estimates that channel for each subcarrier (SC) from each base station transmit (TX) antenna and at each UE receive (RX) antenna. The estimate can be viewed as a three-dimensional channel matrix. The 3D channel matrix represents the MIMO channel estimated over several SCs and is input to the encoder.

The AE encoder is implemented in the UE, and the AE decoder is implemented in the NW. The output of the AE encoder is signalled from the UE to the NW over the uplink. The codeword can be viewed a learned latent representation of the channel. The architecture of an AE (e.g. number of layers, nodes per layer, activation function etc) typically needs to be numerically optimized for CSI reporting via a process called hyperparameter tuning. Properties of the data (e.g., CSI-RS channel estimates), the channel size, uplink feedback rate, and hardware limitations of the encoder and decoder all need to be considered when optimizing the AE's architecture.

The weights and biases of an AE (with a fixed architecture) are trained to minimize the reconstruction error (the error between the input X and output \hat{X}) on some training dataset. For example, the weights and biases can be trained to minimize the mean squared error (MSE) (X− [symbol] )². Model training is typically done using some variant of the gradient descent algorithm on a large training data set. To achieve good performance during live operation, the training data set should be representative of the actual data the AE will encounter during live operation.

In the dual-sided CSI compression, the output of the UE-side encoder needs to be communicated over the air interface to the gNB decoder with the assigned CSI reporting payload and, therefore, needs to be quantized to a finite number of bits (e.g., 1-4 bits per sample for the Uplink Control Information (UCI)) to obtain an efficient transmission, as shown in FIG. 5. FIG. 5 Illustrates a quantization operation at the output of the encoder to fit the CSI payload over the air interface. Accordingly, a quantization layer is usually connected at the output of the encoder or directly included in the encoder. The quantization layer quantizes the output of each neuron of the encoder output layer (the bottleneck layer of AE) to generate bits to fit the CSI reporting payload in the UCI. In relation to the AI/ML model training, this quantization may be done only during the inference (i.e., quantization non-aware training) or may also be included during the training (i.e., quantization-aware training) (Reference [5]).

Pre-processing for input data to the AE—A proper pre-processing on the input to the encoder can greatly reduce the size and complexity for designing and/or training an AI/ML model, and in the meantime, improving the scalability and transferability of the model. In the CSI compression, a pre-processing method could be a transformation of the channel from antenna-frequency domain to beam-delay domain. In addition, the pre-processing is used to reduce the need for multiple models depending on bandwidth variation and variation in the number of antenna ports at the gNB.

To further explain this, the channel representation in the antenna-frequency domain is usually rich and hard to compress, however, its equivalent form in the beam-delay domain is sparse and easier to compress. Such sparsity, to some extent, reflects the physical interpretation of a propagation channel. That is, it reflects how the numerous sinusoidal signals traverse from the transmitting end, along different paths, to the receiving end. Essentially, each beam can be associated with a certain direction of a propagation path, and each delay can reflect the relative difference in distance if a signal propagates along different paths. Ideally, one can think of each pair of beam and delay is associated with a single propagation path, if there is infinite spatial resolution and delay resolution.

In real propagation environment, dominant paths that contribute to conveying a signal are usually sparse if looking at the whole 3-dimensional (3D) space, which means that the signal cannot reach to the receiver end from any direction. Among other reasons, this is mainly limited by the antenna directivity at both the transmitter and the receiver, as well as the number of objects in the propagation environment that can reflect a signal without introducing significant loss. The above sparsity can be exploited to assist an AI/ML model. For example, the beam-delay domain transformation could help the AI/ML model with an initial feature extraction. Another advantage of this pre-processing is that the beam-delay transformation is achieved using Fast Fourier Transforms (FFTs), for which there are already fast implementations with hardware support. The sparsity can be further exploited by removing a number of insignificant beams and delays, so that the input dimensions could also be reduced with a marginal loss, likely resulting in smaller AI/ML models.

The beam-delay transformation and feature extraction can be applied both cases of explicit channel feedback and eigenvector-based feedback. The explicit channel feedback is discussed in Reference [7]. Herein, the focus is on the implicit eigenvector-based feedback. The first step is that the UE measures the channel on CSI-RS. For example, let the UE has 4 Rx-ports, the configured CSI-format has 32 virtual Tx-ports, and the bandwidth are 52 Resource Blocks (RBs) corresponding to 10 MHz at 15 kHz subcarrier spacing. The feature extraction for eigenvector-based feedback is illustrated in FIG. 6. In particular, FIG. 6 shows the pre-processing for implicit feedback of precoding matrices. The steps are as follows:
1. The UE does a spatial domain DFT on the 32×4 matrix per RB and selects the L strongest beams out of 16 (for one polarization). This is done in a wideband manner, including the spatial oversampling of the spatial-domain (SD) basis, and the same beams are used for both polarizations. The covariance of the beam-space channel is summed over, e.g., 4 RBs to produce a covariance matrix for each subband.
2. For each covariance matrix (per subband) the UE extracts a number of eigenvectors and may select the rank, i.e., number of layers.
3. The UE does a frequency domain DFT per layer, transforming to delay domain, whereafter it selects the M strongest taps. The resulting tensor of dimensions 2L×number of layers×M is called the linear combination coefficients and can be used to reconstruct, by the UE suggested, precoding matrices. A tap is a cluster in the wireless channel through which the signal propagates between the transmitter and the receiver. There can be many clusters in the wireless channel, where each cluster represents the reflections and/or scattering which the signal encounters during the transmission. Each cluster results in a propagation delay and signal attenuation. Accordingly, each tap is associated with a delay and path gain value. In this disclosure, the M such strongest taps are selected (there are >M clusters in the wireless channel through which the signal propagates between the gNB and UE). Further information about taps can be found in 3GPP TS 38.214 v16.7.0, section 5.2.2.2.5.
4. The tensor of linear combination coefficients is used as input in the AI/ML model. The input could be further enhanced with information about the selected beams and taps, noise levels, etc.

AE models for rank>1—There can be several options for AI/ML models when rank>1:
1. Rank specific model
2. Rank common model
3. Layer common and rank independent layer models
4. Layer specific and rank independent layer models
5. Layer common and rank dependent layer models
6. Layer specific and rank dependent layer models

The purpose of this section is to define the range of options and discuss possible pros and cons and specification impact. Furthermore, the fact that the two-sided model is used where the encoder is deployed at the UE and decoder at the gNB is not visible in these figures, as it is intended to describe the aim of the encoder.

In the following summary of the options for AI/ML models, it is assumed up to rank 4 reporting, and pre-processing in frequency domain is not considered (i.e., assume per subband reporting is assumed in this categorization for simplicity)

### Option 1: Rank Specific Model

Separate AI/ML models are trained per rank value {1,2,3,4} and applied for corresponding ranks to perform inference
Four AI/ML models, one per rank, needs to be trained and deployed
The output payload (#UCI bits) can be optimized and be different for each rank
Rank selection is expected to be outside the AI/ML model, as the UE select the model to use and report the corresponding RI. Legacy rank selection method may be re-used.
UCI (standardized):
   Possibly a latent space payload indicator
   UCI contains the latent space information associated with the preferred precoder for a rank r transmission, for each subband, where r is given by the Rank Indication (RI) field in the UCI
Model output (standardized):
   The model output indicates the preferred precoder (per subband) for a rank r transmission, where r is given by the RI field in the UCI

FIG. 7 shows a rank specific model showing a rank 3 selection by legacy RI selection module. A total of four models need to be trained.

### Option 2: Rank Common Model

One AI/ML model needs to be trained and deployed
Rank selection may be inside the AI/ML model, the AI/ML model also outputs the preferred rank RI
The output payload (#UCI bits) may be optimized to depend on the output rank RI from the model
UCI (standardized):
   Possibly a latent space payload indicator
   UCI contains the latent space information associated with the preferred precoder for a rank r transmission, for each subband, where r is given by the RI field in the UCI
Model output (standardized):
   The model output indicates the preferred precoder (per subband) for a rank r transmission, where r is given by the RI field in the UCI

FIG. 8 shows a rank common model which implies rank 3 specific model is used. A single model needs to be trained.

### Option 3: Layer Common and Rank Independent Layer Models

Pre-processing to define and transform to layers is necessary (e.g., eigenvector)
One AI/ML model is trained to be used for all layers and applied repeatedly for corresponding layers to perform individual inference
   Layers are ordered and numbered, e.g., the lowest layer index corresponds to the largest eigenvalue
The output payload (#UCI bits) is the same for each layer
This approach allows for UE side layer omission (dropping) if the UCI payload is insufficient to carry all layers
UCI (standardized) contains:
   A rank indicator RI
   Possibly a latent space payload indicator for a layer
   The latent space information associated with each of the layers {1,2, . . . ,RI}, ordered after descending eigenvalue magnitude, for each subband
   Each layer latent space is represented by the same number of bits
Model output (standardized):
   The model output indicates the eigenvector(s) of the RI strongest layers, per subband where r is given by the RI field in the UCI

FIG. 9 illustrates a layer common and rank independent model showing a rank 3 selection which implies rank 3 specific model is used consisting of three identical models, one for each layer. A single layer model needs to be trained. A pre-processing step maps the channel to e.g., eigenvectors (layers).

### Option 4: Layer Specific and Rank Independent Layer Models

Pre-processing to extract the layers is necessary (e.g., eigenvector)
Separate AI/ML models are trained per layer value and applied for corresponding layers to perform individual inference
Layers are ordered and numbered, e.g., the lowest layer index corresponds to the largest eigenvalue
Four AI/ML models, one per layer {1,2,3,4}, needs to be trained and deployed
The output payload (#UCI bits) can be optimized and different for each layer
Allows for UE side layer omission (dropping) if the UCI payload is insufficient to carry all layers
UCI (standardized):
   UCI contains
   A rank indicator RI
   Possibly a latent space payload indicator, per layer
   The latent space information associated with each of the layers {1, 2, . . . ,RI}, ordered after descending eigenvalue magnitude, for each subbands
   Each layer latent space is represented by different number of bits
Model output (standardized):
   The model output indicates the eigenvector(s) of the RI strongest layers, per subband where r is given by the RI field in the UCI
   The UCI payload per layer and rank

FIG. 10 illustrates a layer specific and rank independent model showing a rank 3 selection which implies rank 3 specific model is used consisting of three different models, one for each layer. Four layer models need to be trained. A pre-processing step maps the channel to e.g., eigenvectors (layers).

### Option 5: Layer Common and Rank Dependent Layer Models

Pre-processing to extract the layers is necessary (e.g., eigenvector)
Separate AI/ML models are trained for all layers within each rank and applied for corresponding layers to perform individual inference
   Layers are ordered and numbered, e.g., the lowest layer index corresponds to the largest eigenvalue
Four AI/ML models, one layer model per rank {1,2,3,4}, needs to be trained and deployed
The output payload (#UCI bits) can be optimized and different for each rank
Allows for UE side layer omission (dropping) if the UCI payload is insufficient to carry all layers
UCI (standardized):
   UCI contains
   A rank indicator RI
   Possibly a latent space payload indicator, per layer and per rank
   The latent space information associated with each of the layers {1,2, . . . ,RI}, ordered after descending eigenvalue magnitude, for each subbands
   Each layer latent space is represented by different number of bits
Model output (standardized):
   The model output indicates the eigenvector(s) of the RI strongest layers, per subband where r is given by the RI field in the UCI
   The UCI payload per layer and rank

FIG. 11 illustrates a layer common and rank dependent model showing a rank 3 selection which implies rank 3 specific model is used consisting of three identical models, one for each layer. Four layer models need to be trained. A pre-processing step maps the channel to e.g. eigenvectors (layers).

Option 6: Layer specific and rank dependent layer models
Pre-processing to extract the layers is necessary (e.g., eigenvector)
Separate AI/ML models are trained for all layers and for each rank and applied for corresponding layers to perform individual inference
   Layers are ordered and numbered, e.g., the lowest layer index corresponds to the largest eigenvalue
Ten AI/ML models, one layer model per rank {1,2,3,4}, needs to be trained and deployed
The output payload (#UCI bits) can be optimized and different for each rank and each layer within each rank
Allows for UE side layer omission (dropping) if the UCI payload is insufficient to carry all layers
UCI (standardized):
   UCI contains
   A rank indicator RI
   Possibly a latent space payload indicator, per layer and per rank
   The latent space information associated with each of the layers {1, 2, . . . ,RI}, ordered after descending eigenvalue magnitude, for each subbands
   Each layer latent space for each rank is represented by different number of bits
Model output (standardized):
   The model output indicates the eigenvector(s) of the RI strongest layers, per subband where r is given by the RI field in the UCI
   The UCI payload per layer and rank

FIG. 12 illustrates a layer specific and rank dependent model showing a rank 3 selection which implies rank 3 specific model is used consisting of three different models, one for each layer. Ten layer models need to be trained. A pre-processing step maps the channel to e.g. eigenvectors (layers)

System aspects of Autoencoder-based CSI reporting—Running data-driven algorithms in a communications network requires a different type of life cycle management (LCM) than what has been used traditionally (Reference [6]). For example, the models need to be trained on data, deployed, and may be updated (in one way or another) when new data is collected. 3GPP has agreed to study LCM aspects for AI/ML based on the existence of a Model ID (Reference [7]). Based on such a model ID, the gNB may be able derive some AE model information.

### SUMMARY

There currently exist certain challenge(s). When the encoder at the UE compresses, quantizes, and feedbacks the layer information of the estimated channel, for example, the eigenvectors per layer, to the gNB, it can do so by using the same number of bits per layer or different number of bits per layer depending on the rank and/or the ordering of the layers. The UE has to explicitly signal to the gNB the mapping between the feedback bits to the layers, such that gNB can reconstruct the layer information by processing the bits in the correct order. This requires additional UCI overhead. Further, with a fixed CSI payload configured by the gNB, the additional UCI overhead may reduce the number of bits available for feedback of the compressed layer information, thereby hampering the reconstruction performance at the gNB.

Certain aspects of the disclosure and their embodiments may provide solutions to these or other challenges. The proposed solution provides methodology for feedback of compressed and quantized information from the encoder deployed at the UE to the decoder deployed at the gNB for each layer of the estimated rank without additional UCI overhead.

According to a first aspect, there is provided a method performed by a user equipment, UE. The method comprises: using an encoder of an autoencoder to compress multiple input multiple output, MIMO, channel state information, CSI, for a channel between the UE and a base station; forming a CSI report using a mapping between quantised bits representing the compressed MIMO CSI and layers of the channel, wherein the mapping is dependent on an estimated rank for the channel and/or a layer order; and sending, to the base station, the CSI report and a rank indication for the estimated rank.

According to a second aspect, there is provided a method performed by a base station using multi-user multiple input multiple output, MIMO. The method comprises: receiving, from a user equipment, UE, a channel state information, CSI, report comprising quantised bits representing compressed MIMO CSI for a channel between the UE and the base station, and a rank indication for the channel; and using a decoder of an autoencoder to decompress the compressed MIMO CSI based on (i) the rank indication and (ii) a mapping between quantised bits representing the compressed MIMO CSI and layers of the channel, wherein the mapping is dependent on an estimated rank for the channel and/or a layer order.

According to a third aspect, there is provided a computer program product comprising a computer readable medium having computer readable code embodied therein, the computer readable code being configured such that, on execution by a suitable computer or processor, the computer or processor is caused to perform the method according to the first aspect, the second aspect, or any embodiment thereof.

According to a fourth aspect, there is provided a user equipment, UE, configured to perform the method according to the first aspect or any embodiment thereof.

According to a fifth aspect, there is provided a user equipment, UE, comprising a processor and a memory, said memory containing instructions executable by said processor whereby said UE is operative to perform the method according to the first aspect or any embodiment thereof.

According to a sixth aspect, there is provided a base station configured to perform the method according to the second aspect or any embodiment thereof.

According to a seventh aspect, there is provided a base station comprising a processor and a memory, said memory containing instructions executable by said processor whereby said base station is operative to perform the method according to the second aspect or any embodiment thereof.

According to an eighth aspect, there is provided a user equipment, comprising: processing circuitry configured to cause the user equipment to perform any of the steps of any of the methods according to the first aspect or any embodiment thereof; and power supply circuitry configured to supply power to the processing circuitry.

According to a ninth aspect, there is provided a base station, comprising: processing circuitry configured to cause the base station to perform any of the steps of any of the methods according to the second aspect or any embodiment thereof; and power supply circuitry configured to supply power to the processing circuitry.

According to a tenth aspect, there is provided a user equipment (UE), the UE comprising: an antenna configured to send and receive wireless signals; radio front-end circuitry connected to the antenna and to processing circuitry, and configured to condition signals communicated between the antenna and the processing circuitry; the processing circuitry being configured to perform any of the steps of any of the methods according to the first aspect or any embodiment thereof; an input interface connected to the processing circuitry and configured to allow input of information into the UE to be processed by the processing circuitry; an output interface connected to the processing circuitry and configured to output information from the UE that has been processed by the processing circuitry; and a battery connected to the processing circuitry and configured to supply power to the UE.

Certain embodiments may provide one or more of the following technical advantage(s). The proposed solution provides methodology for an implicit mapping between the feedback bits from the encoder deployed at the UE to the layer information based on the RI and/or the layer ordering, which allows the base station (e.g. gNB) to reconstruct the layer information through the decoder without additional UCI overhead. Further solutions allowing explicit signaling between the gNB and the UE are discussed to provide a more flexible configuration for the layer information processing.

### BRIEF DESCRIPTION OF THE DRAWINGS

Some of the embodiments contemplated herein will now be described more fully with reference to the accompanying drawings, in which:

FIG. 1 illustrates MU-MIMO operations;

FIG. 2 illustrates CSI type II feedback;

FIG. 3 illustrates a fully connected autoencoder;

FIG. 4 illustrates the use of an autoencoder for CSI compression;

FIG. 5 illustrates a quantization operation at the output of the encoder to fit a CSI payload over the air interface;

FIG. 6 illustrates pre-processing for implicit feedback of precoding matrices;

FIG. 7 illustrates a rank specific model showing a rank 3 selection by a legacy RI selection module;

FIG. 8 illustrates a rank common model which implies a rank 3 specific model is used;

FIG. 9 illustrates a layer common and rank independent model showing a rank 3 selection which implies rank 3 specific model is used consisting of three identical models, one for each layer;

FIG. 10 illustrates a layer specific and rank independent model showing a rank 3 selection which implies rank 3 specific model is used consisting of three different models, one for each layer;

FIG. 11 illustrates a layer common and rank dependent model showing a rank 3 selection which implies rank 3 specific model is used consisting of three identical models, one for each layer;

FIG. 12 illustrates a layer specific and rank dependent model showing a rank 3 selection which implies rank 3 specific model is used consisting of three different models, one for each layer;

FIG. 13 is a flow chart/signalling diagram illustrating operations of a gNB and UE according to some exemplary embodiments;

FIG. 14 illustrates an architecture of the channel eigenvector feedback approach for mapping between feedback bits and layer information corresponding to an estimated rank;

FIG. 15 illustrates the bottleneck layer for the layer specific and rank independent model with different quantization bits per channel layer;

FIG. 16 illustrates the bottleneck layer for the layer specific and rank independent model with different sizes of the bottleneck per channel layer;

FIG. 17 illustrates the bottleneck layer for the layer specific and rank independent model with different sizes of the bottleneck per channel layer;

FIG. 18 illustrates the bottleneck layer for the layer common and rank dependent model with different quantization bits per channel layer;

FIG. 19 illustrates the bottleneck layer for the layer common and rank dependent model with different sizes of the bottleneck per channel layer;

FIG. 20 illustrates the bottleneck layer for the layer common and rank dependent model with different sizes of the bottleneck per channel layer;

FIG. 21 illustrates the bottleneck layer for the layer specific and rank dependent model with different quantization bits per channel layer;

FIG. 22 illustrates the bottleneck layer for the layer specific and rank dependent model with different sizes of the bottleneck per channel layer;

FIG. 23 illustrates the bottleneck layer for the layer specific and rank dependent model with different sizes of the bottleneck per channel layer;

FIG. 24 illustrates the bottleneck layer of FIG. 16 without neurons that have a 0-bit output;

FIG. 25 illustrates the bottleneck layer of FIG. 19 without neurons that have a 0-bit output;

FIG. 26 illustrates the bottleneck layer of FIG. 22 without neurons that have a 0-bit output;

FIG. 27 shows a layer specific and rank dependent/independent approach for r̅=2;

FIG. 28 is a graph illustrating mean user throughput vs served traffic performance for the layer specific and rank dependent AE model;

FIG. 29 is a flow chart illustrating a method performed by a UE in accordance with some embodiments;

FIG. 30 is a flow chart illustrating a method performed by a base station in accordance with some embodiments;

FIG. 31 shows an example of a communication system in accordance with some embodiments;

FIG. 32 shows a UE in accordance with some embodiments;

FIG. 33 shows a RAN network node in accordance with some embodiments; and

FIG. 34 is a block diagram illustrating a virtualization environment in which functions implemented by some embodiments may be virtualized.

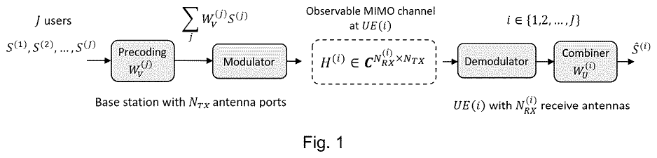

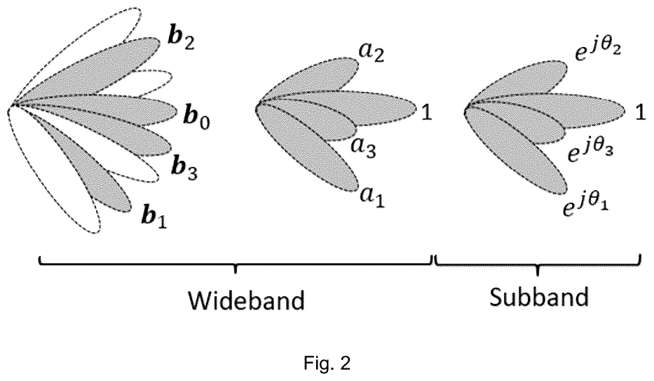

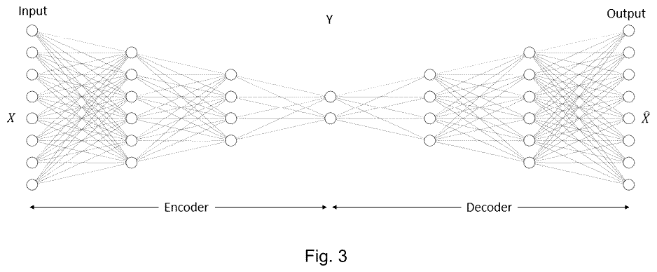

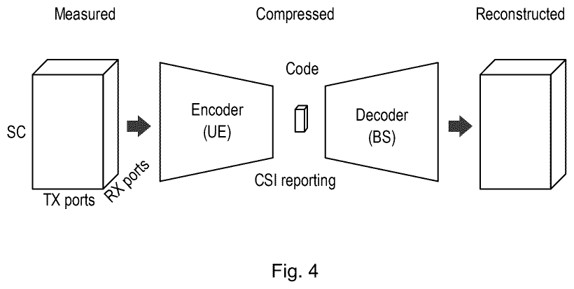

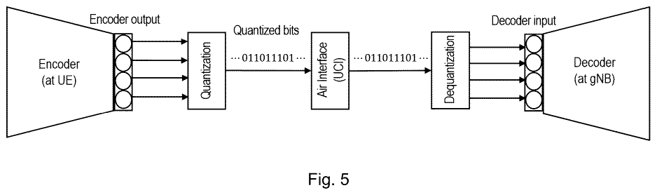

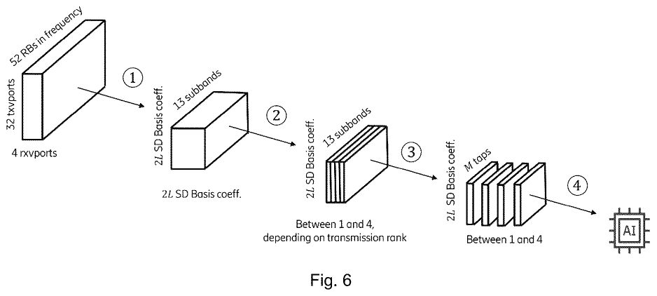

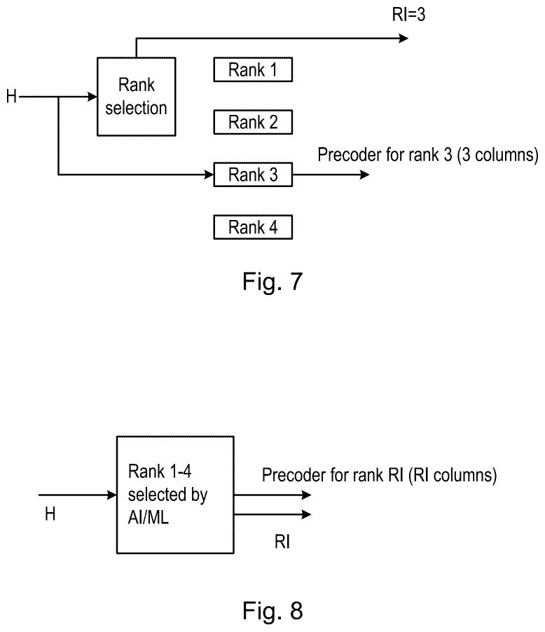

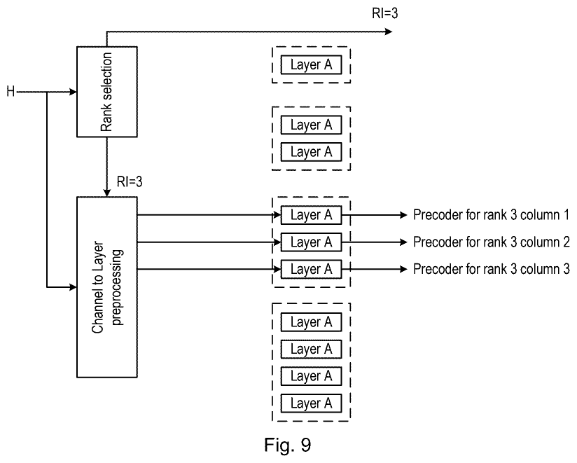

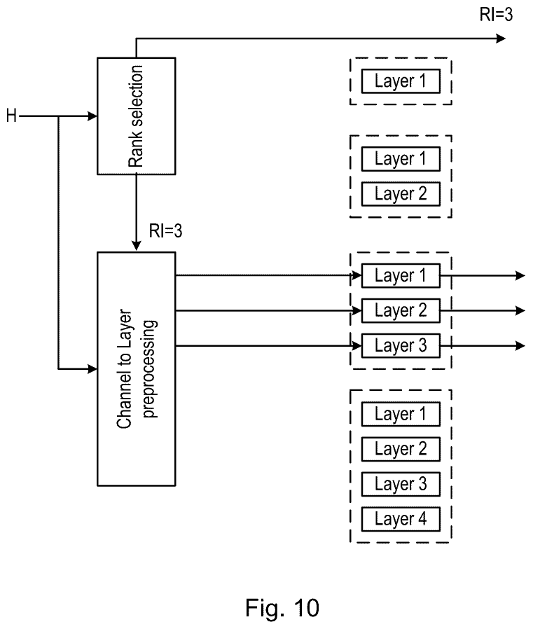

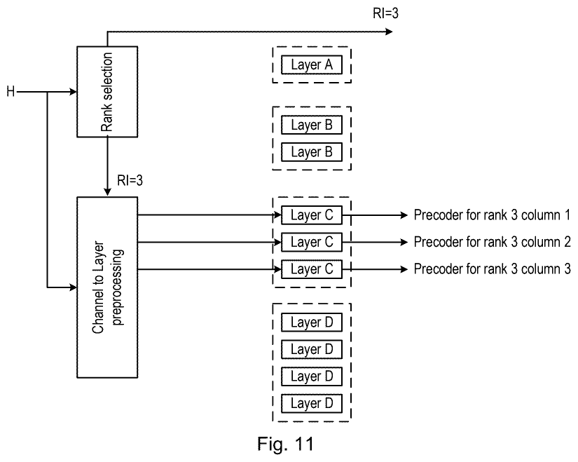

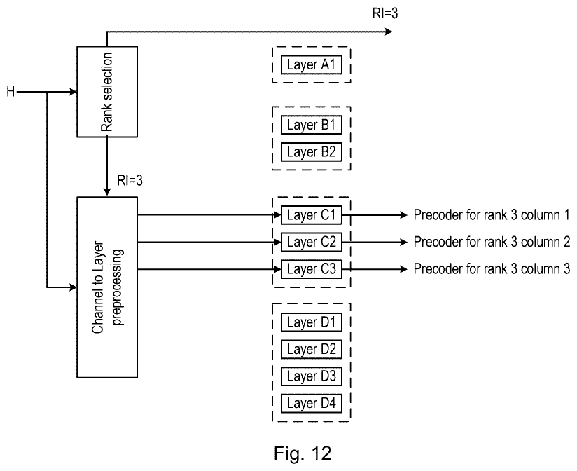

### DETAILED DESCRIPTION

Some of the embodiments contemplated herein will now be described more fully with reference to the accompanying drawings. Embodiments are provided by way of example to convey the scope of the subject matter to those skilled in the art.

As noted above, this disclosure provides a methodology for feedback of compressed and quantized information from the encoder deployed at the UE to the decoder deployed at the gNB for each layer of the estimated rank without additional UCI overhead.

The methodology involves a pre-defined mapping between the feedback bits and the layer information based on the estimated rank and/or layer ordering. The gNB infers the bits required to reconstruct the layer information at the decoder through the rank indicated by the UE.

Further methodology allowing explicit signaling between the gNB and the UE is discussed to provide a more flexible configuration for the layer information processing.

Herein, an implicit mapping of either the quantization bits per neuron or/and the number of feedback bits at the output of the encoder deployed at the UE to the layer information, i.e., the eigenvectors per layer, based on the estimated rank and/or the corresponding layer ordering can be defined such that the gNB can reconstruct the layer information at the decoder output based on the indicated rank without additional UCI overhead. Such mapping option/s may be included in specification text or communicated between gNB and UE vendors via, e.g., bilateral agreements. Alternatively, such mapping may be communicated via over-the-air signaling among the gNB and the UE, e.g., the UE may indicate the used mapping from the options available in the specification or the gNB may specify the mapping that the UE should apply. For the cases where such signaling is performed over-the-air, embodiments are disclosed in which new fields are added to, e.g., the UECapabilityEnquiry RRC message, the UECapabilityInformation RRC message, the Downlink Control Information (DCI), or the UCI.

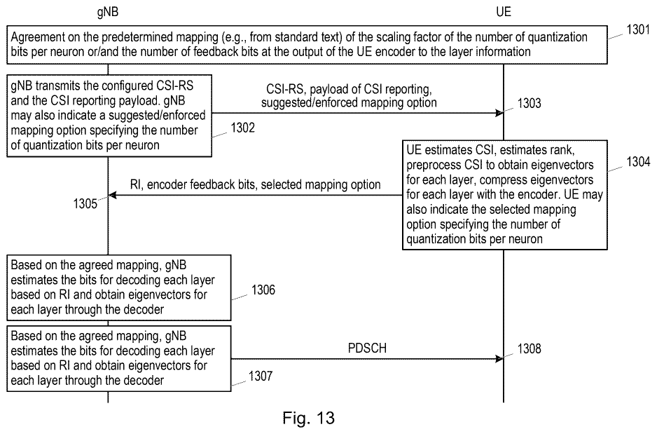

Once such mapping is agreed/defined, changes that can be introduced to the system operation are underlined below. The below methods, and variants thereof, are summarized in the flow chart/signalling diagram of FIG. 13. Step 1301 in FIG. 13, which is performed by the gNB and/or the UE, represents the agreement/definition of the mapping described above. In step 1302, the gNB transmits the configured CSI-RS and the CSI reporting payload to the UE. The gNB may also indicate a suggested/enforced mapping option specifying the number of quantization bits per neuron.

A method in a UE according to some exemplary embodiments:
The UE receives (as shown by signal 1303) the CSI-RS from the gNB along with the CSI reporting payload size, where the qNB may further configure the maximum number of quantization bits per neuron to be used by the encoder at the UE according to the CSI reporting Payload and the AE model.
   The maximum number of quantization bits per neuron that a UE encoder may implement may be bounded by the specification.
The UE estimates (in step 1304) the downlink (DL) channel with the received CSI-RS, determines a RI, and further processes the channel to obtain the eigenvectors per layer based on the selected RI.
Also in step 1304, the UE compresses and quantizes the eigenvectors per layer through the encoder with a pre-defined methodology based on the selected RI and maps the quantized information according to a pre-defined mapping based on the selected RI.
The UE reports (step 1305) the output of the AI-based processing unit along with the RI to the gNB in the CSI report, where the UE may further indicate the selected mapping option specifying the number of quantization bits per neuron based on layer order and/or selected RI.

A method in a base station (e.g., a gNB) according to some exemplary embodiments:
Via signal 1305, the gNB receives the feedback bits from the UE in the CSI report along with the indicated RI.
   The qNB may further receive selected mapping information from the UE to process the feedback bits per layer based on RI.
With the pre-defined (and/or UE signaled) mapping between the feedback bits and eigenvectors per layer based on the RI, the gNB reconstructs the eigenvectors at the output of the decoder (step 1306).
In step 1307, the gNB can further process the estimated eigenvectors per layer to obtain the precoders per layer for Physical Downlink Shared Channel (PDSCH) transmission. Signal 1308 represents the transmission of the PDSCH.

### System Overview

The UE estimates the downlink (DL) channel based on the configured DL reference signals (e.g., CSI-RS, Demodulation Reference Signal (DMRS), etc.), and produces a channel estimate H, for example, in the antenna-frequency domain. The raw channel H can be expressed per CSI-RS port (TX side), per receive antenna (RX side), per frequency subband, and measured at one or more points in time. Hence, in the most general cases, the channel H is a four-dimensional matrix or tensor.

The raw channel estimate H is leveraged to estimate the appropriate rank for the downlink transmission and further processed to extract the eigenvector corresponding to each layer according to the estimated rank r. The eigenvectors per layer based on r is denoted by e_{r,l}_{ᵣ}, where lᵣ=1, 2, . . . , r. e_{r,l}_{ᵣ} is a tensor with dimension equal to number of CSI-RS ports×number of layers×number of frequency subbands. The extracted e_{r,l}_{ᵣ} are compressed and quantized at the encoder into bits, such that bₗ_{ᵣ} represents the bits for quantizing the lᵣ-th layer. Subsequently, the concatenated bits across all the layers, denoted by b_{AE}=[b₁, b₂, . . . , bₗ_{ᵣ}], along with the rank indication (RI) is reported back to the gNB as part of the uplink CSI report.

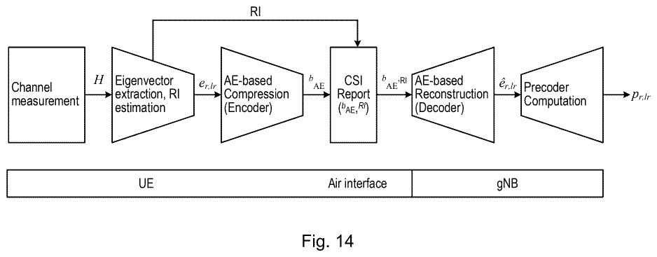

The CSI report comprising of b_{AE} and RI is fed to the decoder deployed at the gNB to reconstruct the eigenvectors per layer, denoted by ê_{r,l}_{ᵣ}, Lᵣ=1, 2, . . . , r. The gNB can further process the eigenvectors to obtain the precoders for each layer, denoted by pr_{r,l}_{ᵣ}, lᵣ=1, 2, . . . ,r, for the transmission of the PDSCH. The processing of the channel to produce the precoders for each transmitted layer through the autoencoder (AE) is shown in FIG. 14. FIG. 14 shows the architecture of the channel eigenvector feedback approach for the proposed methodology for mapping between the feedback bits and the layer information corresponding to the estimated rank.

The dimension of raw e_{r,l}_{ᵣ} can be very large depending on the number of CSI-RS ports and the number of subbands, which can make the AE model and training complex. Accordingly, H may be further pre-processed to have reduced dimension compared to the raw eigenvectors per layer based on feature extraction of the eigenvectors. Following the “Pre-processing for input data to the AE” section above, the pre-processing of the channel to extract features of eigenvectors per layer in the beam-delay domain with L SD basis and M delay-taps, results in a linear combination coefficient tensor of dimensions 2L×number of layers×M, denoted by W₂. In a more specific implementation, values for L and M can be chosen from Rel-16 Type-II pre-processing defined in Reference [1] (M depends on the value of pᵥ in 3GPP TS 38.214, where v is the layer index). With the above pre-processing, the encoder at the UE compresses and quantizes W₂, where the reduced dimension of W₂ simplifies the AE model size and training complexity. As pointed out in the “Autoencoders for AI/ML-enhanced CSI reporting” section above, the feedback of NZCs of W₂ contributes to major overhead for Type-II, which can be reduced leveraging feedback through an AE. However, the above pre-processing for eigenvectors requires the UE to explicitly feedback {L, M} back to the gNB with occupies additional UCI overhead.

Note that herein the per-layer input of the encoder is called eigenvectors. However, the term eigenvector is used in a wide sense that incorporates different ways for the UE to extract precoding information for different layers. Examples are:
1. Eigenvectors of the transmit covariance corresponding to the raw channel H, for a fixed frequency index, and in the most general case also a fixed time index.
   This is equivalent to the singular vectors of the raw channel H.
2. Eigenvectors of an (weighted) averaged transmit covariance of the channel H estimated over different time and/or frequency resources. The aggregation can be, e.g., to average the covariance matrices over 2, 4, or 8 RBs in frequency.
   Singular vectors of an (weighted) averaged of the channel H estimated over different time and/or frequency resources.
3. Approximations of eigenvectors expressed in a reduced beam-space, corresponding to a set of DFT-vectors.
   The approximate eigenvectors can correspond to any of 1 or 2 above.
4. Approximations of eigenvectors expressed in a reduced beam-space, corresponding to a set of DFT-vectors; with further compression in time-domain using DFT-bases.
   The approximate eigenvectors can correspond to any of 1 or 2 above.

Likewise, the term eigenvalue is used in a wide sense. The term should be interpreted relative to the term eigenvector, where in general a larger eigenvalue means that the UE estimates better reception quality in the sense of Signal to Noise Ratio (SNR) or Signal to Interference plus Noise Ratio (SINR), for the used precoding vector.

Moreover, herein the concept of ‘network’ and/or a gNB can be understood as a generic network node, gNB, base station, unit within the base station to handle at least some ML operation, relay node, core network node, a core network node that handle at least some ML operations, or a device supporting Device-to-Device (D2D) communication. The node may be deployed in a 5G network, or a 6^{h} Generation (6G) network.

### Embodiments for Implicit Mapping Between Feedback Bits to the Layer Information

In the following embodiments, various methods for the implicit mapping between the feedback bits to the eigenvectors per layer compressed and quantized at the UE are discussed, when the estimated rank is r>1. For this, it is assumed that the UE obtains the eigenvectors per layer from the estimated channel, followed by compressing and quantizing the eigenvectors per layer with the encoder before feedback to the decoder deployed at the gNB. The gNB can use the pre-defined implicit mapping to reconstruct the eigenvectors per layer based on the RI at the output of the decoder. The embodiments are discussed based on the AE models for r>1 described in the “AE models for rank>1” part of the Background section of this disclosure. Note that although the description emphasizes the cases where the rank is larger than 1, the methods can also readily be applied when the UE reports CSI with RI=1.

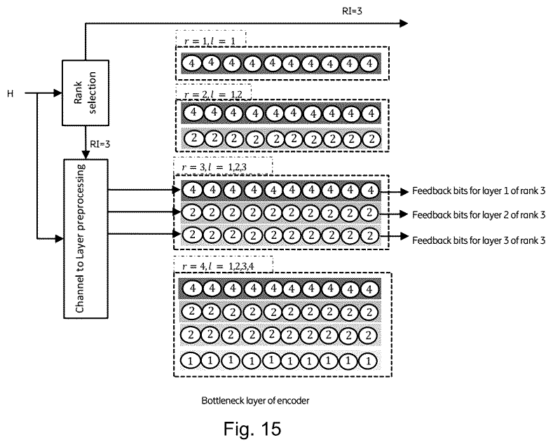

Embodiments for layer specific and rank independent layer models—In one embodiment, for layer specific and rank independent layer models, the number of quantization bits for the neurons of the bottleneck layer at the encoder can be set as function of the layers. Accordingly, the number of quantization bits for neurons of the bottleneck layer can inversely change with increasing order of layers to make the feedback bits fit the CSI reporting payload. Note that the layers can be ordered such that the first layer corresponds to the eigenvector corresponding to the largest eigenvalue. Accordingly, for example, if the bottleneck layer has n_{b} neurons, the number of quantization bits to compress the l-th layer can be set as qᵣ=[Q_{B}/l], where Q_{B} is the maximum quantization bits per neuron of the bottleneck layer of the encoder, r is the estimated rank, such that l∈{1,2, . . . , r}. With the pre-defined mapping between the layers to the number of quantization bits, the gNB can use the first n_{b}Q_{B} feedback bits to reconstruct eigenvector for first layer, the next n_{b} [Q_{b}/2] feedback bits to reconstruct eigenvector for second layer and so on. Hence, assuming n_{b}=10 and Q_{B}=4, and depending on the estimated rank r, the UE feedback n_{b}rqᵣ bits, i.e., 40, 60, 80, 90 bits for r=1, 2, 3, and 4, respectively, to the gNB, as shown in FIG. 15. In particular, FIG. 15 shows the bottleneck layer for the layer specific and rank independent model showing a rank 3 selection where n_{b}=10 and Q_{B}=4. The number in each neuron represents the quantization bits used to quantize the layer information for the specific layer based on the ordering of layers. Here, the quantization bits to quantize the layer information depends on the order of the layer. Note that the encoder uses the same model per layer to compress the layers l∈{1,2, . . . ,r}, independent of the rank as described in Option 4 above (“Layer specific and rank independent layer models”).

In a related embodiment, for layer specific and rank independent layer models, the UE can feedback different number of bits per layer from the bottleneck layer of the encoder. For example, with the bottleneck layer having n_{b} neurons and with the number of quantization bits per neuron set as qᵣ, where r is the estimated rank, the UE can feedback the l-th layer with [n_{b}/l]qᵣ bits. Note that the layers can be ordered such that the first layer corresponds to the eigenvector corresponding to the largest eigenvalue. Accordingly, with the pre-defined mapping between the layers to the number of feedback bits, the gNB can use the first n_{b}qᵣ feedback bits to reconstruct eigenvector for first layer, the next [n_{b}/2]qᵣ feedback bits to reconstruct eigenvector for second layer and so on. Note that the UE can transparently choose the method to select the subset of

$${\sum }_{l = 1}^{r} ⌈ {n}_{b} / l ⌉ {q}_{r}$$

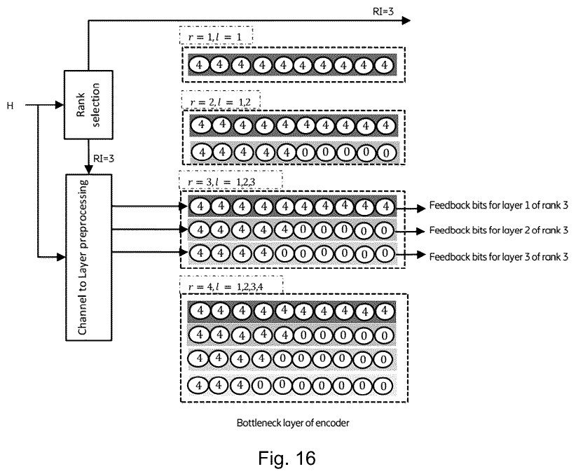

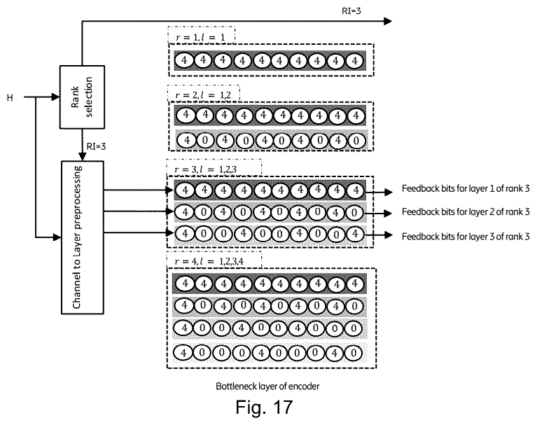

bits out of the generated n_{b}rqᵣ bits. For example, if n_{b}=10 and qᵣ=Q_{B}=4, the UE will generate 40, 80, 120 and 160 bits for r=1, 2, 3 and 4, respectively, at the output of the encoder. Subsequently,
I. Depending on the ordering of the layers, the UE can feedback only the first [n_{b}/l]qᵣ bits out of n_{b} qᵣ bits for each layer, i.e., output from first [n_{b}/l] neurons at the bottleneck layer for each layer, as shown in FIG. 16, or,
II. Depending on the ordering of the layers, the UE can feedback only bits from the first neuron and every l-th neuron after the first neuron of the output layer of the encoder, as shown in FIG. 17.

Based on the above, the UE feedback 40, 60, 76 and 88 bits for r=1, 2, 3 and 4, respectively, to the gNB.

FIG. 16 shows the bottleneck layer for the layer specific and rank independent model showing a rank 3 selection where n_{b}=10 and Q_{B}=4. The number in each neuron represents the quantization bits used to quantize the layer information for the specific layer based on the ordering of layers. Here, the feedback bits per layer is taken from initial portion of total feedback bits per layer depending on the order of the layer. Note that the encoder uses the same model per layer to compress the layers l∈{1,2, . . . ,r}, independent of the rank as described in Option 4 above (“Layer specific and rank independent layer models”).

FIG. 17 shows the bottleneck layer for the layer specific and rank independent model showing a rank 3 selection where n_{b}=10 and Q_{B}=4. The number in each neuron represents the quantization bits used to quantize the layer information for the specific layer based on the ordering of layers. Here, the feedback bits per layer is taken from non-consecutive neurons in the bottleneck layer of the encoder depending on the order of the layer. Note that the encoder uses the same model per layer to compress the layers l∈{1,2, . . . ,r}, independent of the rank as described in Option 4 above (“Layer specific and rank independent layer models”).

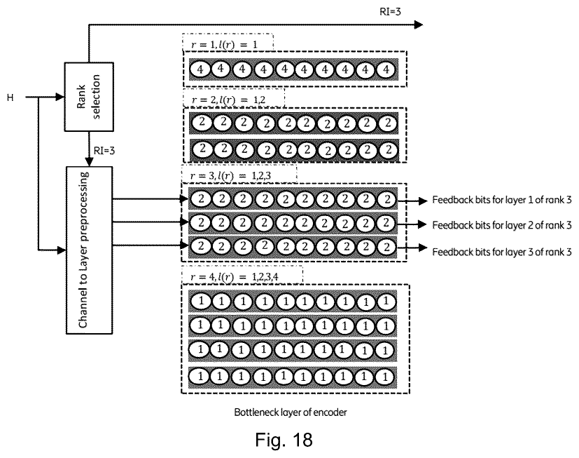

Embodiments for layer common and rank dependent layer models—In one embodiment, for layer common and rank dependent layer models, the number of quantization bit for the neurons of the bottleneck layer is set as function of the estimated rank. Accordingly, the quantization bits can inversely change with increasing rank to make the feedback bits fit the CSI reporting overhead. For example, if the bottleneck layer has n_{b} neurons, the number of quantization bits to compress the layers for the r-th indicated rank can be set as qᵣ=Q_{B}/r], where Q_{B} is the maximum quantization bits per neuron of the bottleneck layer of the encoder, r is the estimated rank. With the pre-defined mapping between the indicated rank to the number of quantization bits, the gNB can use the first n_{b}Q_{B} feedback bits to reconstruct eigenvector for first layer, the next n_{b} [Q_{b}/2] feedback bits to reconstruct eigenvector for second layer and so on. Accordingly, assuming n_{b}=10 and Q_{B}=4, and depending on the estimated rank r, the UE feedback n_{b}rqᵣ bits, i.e., 40, 40, 48, 48 bits for r=1, 2, 3 and 4, respectively, as shown in FIG. 18.

FIG. 18 shows the bottleneck layer for the layer common and rank dependent model showing a rank 3 selection where n_{b}=10 and Q_{B}=4. The number in each neuron represents the quantization bits used to quantize the layer information for the specific layer based on the estimated rank. Here, the quantization bits to quantize the layer information depends on the estimated rank. Note that the encoder uses the same model for all the layers based on the estimated r to compress the layers l(r)∈{1,2, . . . ,r}, as described in Option 5 above (Layer common and rank dependent layer models).

In a related embodiment, for layer common and rank dependent layer models, the UE can feedback different number of bits per layer from the bottleneck layer of the encoder, depending on the estimated rank r. For example, with the bottleneck layer having n_{b} neurons and the number of quantization bits per neuron set as qᵣ, the UE can feedback [n_{b}/r]qᵣ qbits per layer to the gNB. Accordingly, the gNB can interpret the feedback bits for decoding eigenvector of each layer based on the indicated rank, i.e., the gNB can use the first [n_{b}/r]qᵣ feedback bits to reconstruct the eigenvector for first layer, the next [n_{b}/r]ᵣqᵣ feedback bits to reconstruct the eigenvector for second layer and so on.

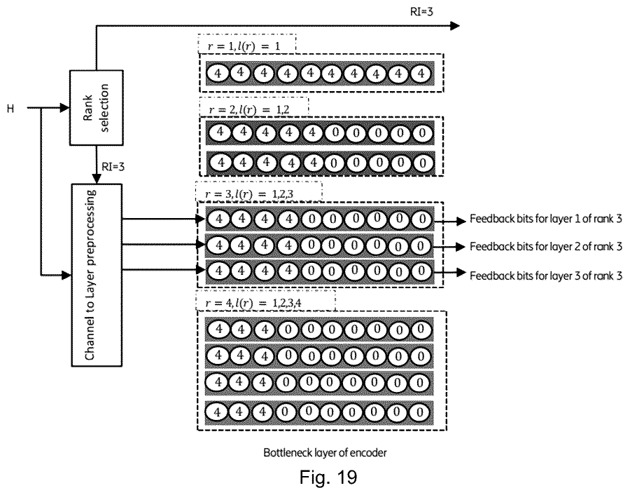

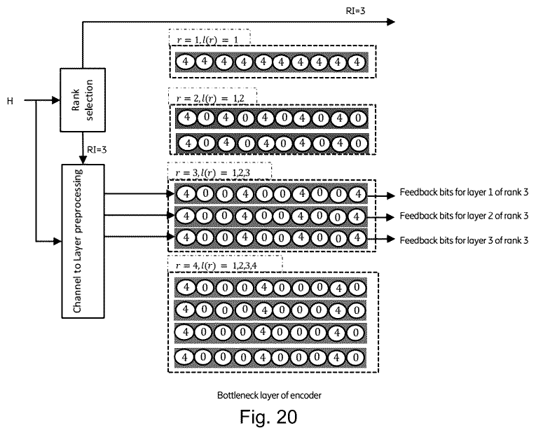

Note that the UE can transparently choose the method to select the subset of [n_{b}/r]rqᵣ bits out of the generated n_{b}rqᵣ bits. For example, if n_{b}=10 and qᵣ=Q_{B}=4, the UE will generate 40 bits at the output of the encoder for each layer or 40, 80, 120 and 160 bits for r=1, 2, 3 and 4, respectively. Subsequently:
I. Depending on the estimated rank r, the UE can feedback only the first [n_{b}/r]qᵣ bits out of n_{b}qᵣ bits for each layer, i.e., output from first [n_{b}/r] neurons for each layer, as shown in FIG. 19, or,
II. Depending on the estimated rank r, the UE can feedback bits only from the first neuron and every r-th neuron after the first neuron of the output layer of the encoder, as shown in FIG. 20.

Based on the above, the UE feedback 40, 40, 48 and 48 bits for r=1, 2, 3 and 4, respectively, to the gNB.

FIG. 19 shows the bottleneck layer for the layer common and rank dependent model showing a rank 3 selection where n_{b}=10 and Q_{B}=4. The number in each neuron represents the quantization bits used to quantize the layer information for the specific layer based on the estimated rank. Here, the feedback bits per layer is taken from initial portion of total feedback bits per layer depending on the estimated rank. Note that the encoder uses the same model for all the layers based on the estimated r to compress the layers l(r)∈{1,2, . . . ,r}, as described in Option 5 above (Layer common and rank dependent layer models).

FIG. 20 shows the bottleneck layer for the layer common and rank dependent model showing a rank 3 selection where n_{b}=10 and Q_{B}=4. The number in each neuron represents the quantization bits used to quantize the layer information for the specific layer based on the estimated rank. Here, the feedback bits per layer is taken from non-consecutive neurons in the bottleneck layer of the encoder depending on the estimated rank. Note that the encoder uses the same model for all the layers based on the estimated r to compress the layers l(r)∈{1,2, . . . ,r}, as described in Option 5 above (Layer common and rank dependent layer models).

Embodiments for layer specific and rank dependent layer models—In one embodiment, for layer specific and rank dependent layer models, the number of quantization bits for the neurons of the bottleneck layer is set as function of the estimated rank and ordering of the corresponding layers. Accordingly, the quantization bits can inversely change with increasing rank and the ordering of the corresponding layers to make the feedback bits fit the CSI reporting payload. The layers can be ordered such that the first layer corresponds to the eigenvector corresponding to the largest eigenvalue. For example, if the bottleneck layer has n_{b} neurons, the number of quantization bits to compress the lᵣ-th layer can be set as qᵣ=[Q_{B}/(rlᵣ)], where Q_{B} is the maximum quantization bits per neuron of the bottleneck layer of the encoder, r is the estimated rank and lᵣ is the corresponding layer, such that lᵣ=1,2, . . . , r. With the pre-defined mapping between the indicated rank r and the corresponding layers to the number of quantization bits, the gNB can use the first n_{b}[Q_{B}/r] feedback bits to reconstruct eigenvector for first layer, the next n_{b} [Q_{B}/2ᵣ] feedback bits to reconstruct eigenvector for second layer and so on. Accordingly, assuming n_{b}=10 and Q_{B}=4 and depending on the estimated rank r, the UE feedback n_{b}rqᵣ bits, i.e., 40, 30, 40, 40 bits for r=1, 2, 3, and 4, respectively, to the gNB.

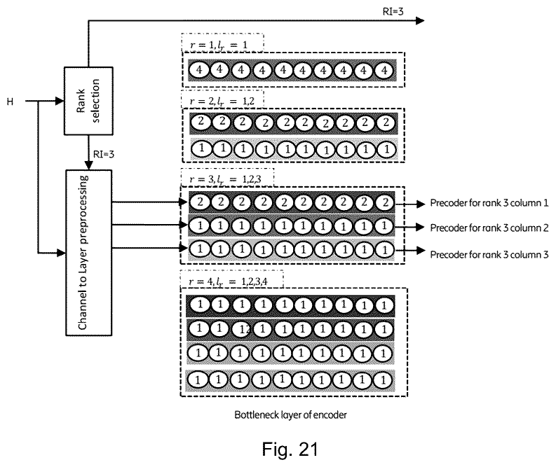

FIG. 21 shows the bottleneck layer for the layer specific and rank dependent model showing a rank 3 selection where n_{b}=10 and Q_{B}=4. The number in each neuron represents the quantization bits used to quantize the layer information for the specific layer based on the estimated rank and the ordering of corresponding layers. Here, the quantization bits to quantize the layer information depends on the estimated rank and the order of the corresponding layer. Note that the encoder uses the different model for different rank and the corresponding layers based on the estimated r to compress the layers lᵣ∈{1,2, . . . ,r}, as described in Option 6 above (“Layer specific and rank dependent layer models”).

In a related embodiment, for layer specific and rank dependent layer models, the gNB can decode the feedback bits by processing bits for different layers depending on the indicate rank and the ordering of the corresponding layers. For example, with the bottleneck layer having n_{b} neurons and the number of quantization bits per neuron set as qᵣ, where r is the indicated rank by the UE, the UE can feedback the lᵣ-th layer with [n_{b}/rlᵣ]qᵣ bits to the gNB. Accordingly, the gNB can interpret the quantization bits for each layer based on the indicated rank and the layer order, i.e., the gNB can use the first [n_{b}/r]qᵣ bits to reconstruct the eigenvector for first layer, the next [n_{b}/2r]qᵣ bits to reconstruct the eigenvector for second layer and so on. Accordingly, the UE can transparently choose the method to select the subset of

$${\sum }_{{l}_{r} = 1}^{r} ⌈ {n}_{b} / {l}_{r} r ⌉ {q}_{r}$$

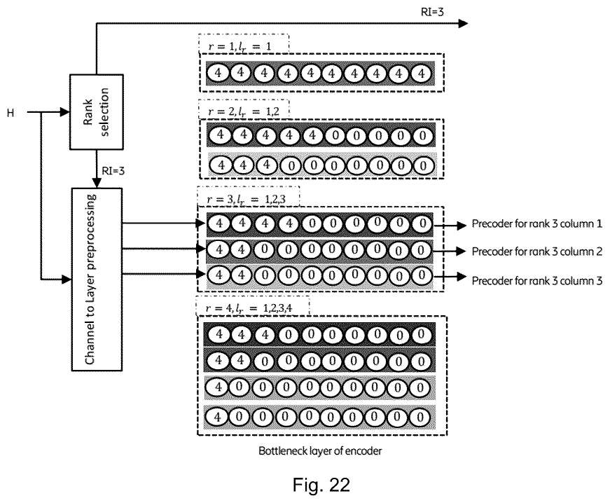

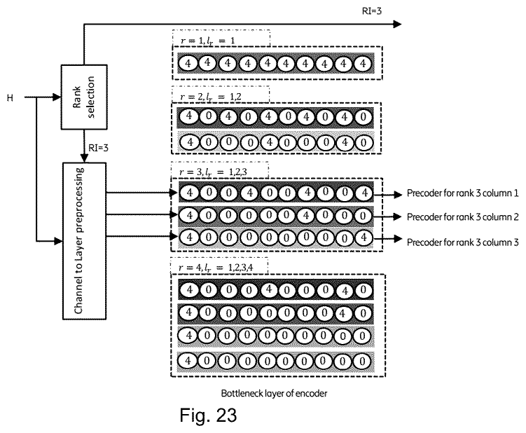

bits out of the generated n_{b}rqᵣ bits for the estimated rank r. For example, if n_{b}=10 and qᵣ=Q_{B}=4, the UE will generate 40 bits at the output of the encoder for each layer or 40, 80, 120 and 160 bits for r=1, 2, 3 and 4, respectively. Subsequently,
I. Depending on the estimated rank r and the ordering of the corresponding layers, the UE can feedback only the first [n_{b}/lᵣ]qᵣ bits out of n_{b}qᵣ bits for each layer, i.e., output from first [n_{b}/lᵣr] neurons for each layer, as shown in FIG. 22, or,
II. Depending on the estimated rank r, the UE can feedback bits only from the first neuron and every (rlᵣ)-th neuron after the first neuron of the output layer of the encoder, as shown in FIG. 23.

Based on the above, the UE will feedback 40, 32, 32 and 28 bits for r=1, 2, 3 and 4, respectively, to the gNB.

FIG. 22 shows the bottleneck layer for the layer specific and rank dependent model showing a rank 3 selection where n_{b}=10 and Q_{B}=4. The number in each neuron represents the quantization bits used to quantize the layer information for the specific layer based on the estimated rank and ordering of the layers. Here, the feedback bits per layer is taken from initial portion of total feedback bits per layer depending on the estimated rank and order of the layer. Note that the encoder uses the different model for different rank and the corresponding layers based on the estimated r to compress the layers lᵣ∈{1,2, . . . ,r}, as described in Option 6 above (“Layer specific and rank dependent layer models”).

FIG. 23 shows the bottleneck layer for the layer specific and rank dependent model showing a rank 3 selection where n_b=10 and Q_B=4. The number in each neuron represents the quantization bits used to quantize the layer information for the specific layer based on the estimated rank and ordering of the layers. Here, the feedback bits per layer is taken from non-consecutive neurons in the bottleneck layer of the encoder depending on the estimated rank and order of the layer. Note that the encoder uses the different model for different rank and the corresponding layers based on the estimated r to compress the layers lᵣ∈{1,2, . . . ,r}, as described in Option 6 above (“Layer specific and rank dependent layer models”).

Dependence on rank and/or layer—In the above description, the denominator value to determine the value of the quantization bit and/or the value of number of pre-quantized encoder output is based on the value of r and/or lᵣ. It should be understood that the above should serve as a preferred formula. In another example of implementation, the value of the denominator may be pre-determined, e.g., in the standard text. For example, the denominator value can be set to a first, a second, a third, and a fourth denominator value for the first, the second, the third, and the fourth layer or rank, respectively. The set of value may be different depends on the number of configured layers. E.g., a first set of denominator values is applied for a first value of configured layer and a second set of denominator values is applied for a second value of configured layer. Similarly, the set of denominator values may also additionally or optionally depend on the number of neurons of the bottleneck.

Similarly, in the above description, there are embodiments describing situations when the UE can feedback bits only from the first neuron and every k(r, l)-th neuron, where the values of k(r, l) are exemplified above as
k(r,l)=1, the layer index, in the “Embodiments for layer specific and rank independent layer models section” above,
k(r,l)=r, the rank, in the “Embodiments for layer common and rank dependent layer models” section above, and
k(r,l)=lᵣr, the rank-specific layer index lᵣ and the rank r, in the “Embodiments for layer specific and rank dependent layer models” section above.

It should be understood that the above should serve as preferred formulas. In another example of implementation, the values of the k(r, l) may be pre-determined, e.g., in the standard text. For example, the values of k (r, l) may depend on one or both of the variables r and, l and may be written out as specific values in a table. Similarly, k (r, l) may also additionally or optionally depend on the number of neurons of the bottleneck, i.e., be replaced by k(r, l, n_{b}).

Implementation examples—In some of the above embodiments, the bottleneck layer has n_{b} neurons and the output of some of those are quantized with 0 bits. These embodiments can also be implemented by ML-models that exclude those bottleneck neurons. A few examples are outlined below.

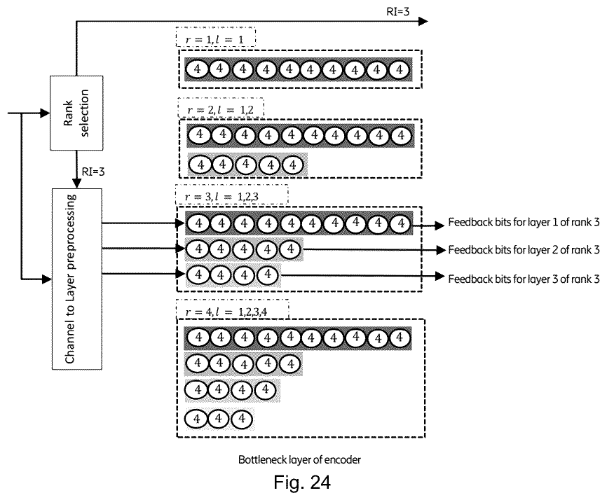

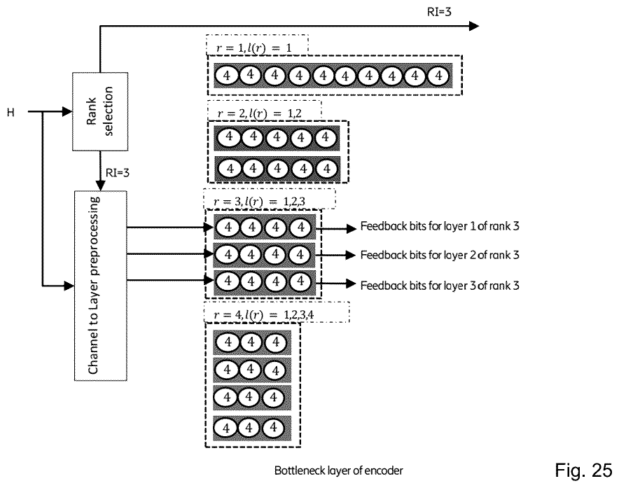

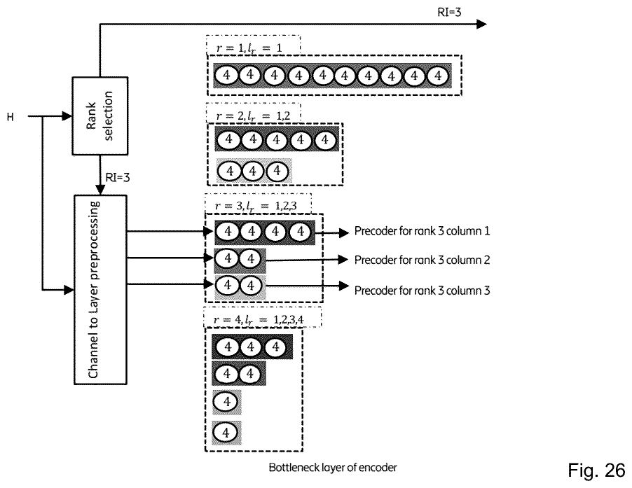

FIG. 24 illustrates this implementation difference in the example described in FIG. 16 for the layer specific and rank independent layer models. FIG. 25 illustrates this implementation difference in the example described in FIG. 19 for the layer common and rank dependent layer models. FIG. 26 illustrates this implementation difference in the example described in FIG. 22 for the layer specific and rank dependent layer models.

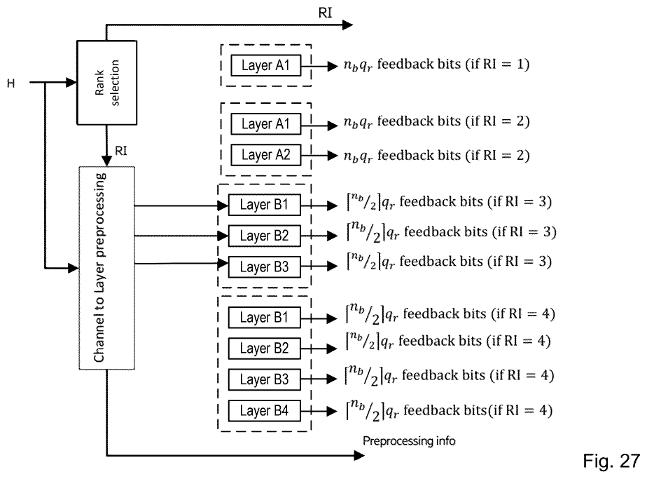

In some embodiments, with the models described for r>1 described in the “AE models for rank>1” section, models with different variations or subset of layer specific/common and rank dependent/independent methods are not precluded. For example, a layer specific and rank dependent model can be defined where AEs are trained separately for all layers for r≤r̅ and different AEs are trained separately for all layers for r>r̅. The different models for r≤r̅ and r>r̅ can refer to the processing defined in the above embodiments, which can result in different processing of latent space for each layer depending on the rank by varying either the quantization bits across the neurons of the bottleneck layers and/or the number of active neurons in the bottleneck layer. Accordingly, with the bottleneck layer having n_{b} neurons and the number of quantization bits per neuron set as qᵣ and with a layer ordering, the UE can feedback n_{b}qᵣ bits and [n_{b}/r̅]qᵣ bits per layer for r≤r̅ and r>r̅, respectively. Subsequently, the gNB can interpret the feedback bits for decoding eigenvector of each layer based on the indicated rank. Specifically, the gNB can sequentially use n_{b}qᵣ or [n_{b}/r̅]qᵣ feedback bits to reconstruct the eigenvector for each layer if r≤r̅ or [n_{b}/r̅]qᵣ, respectively. With this model, in one example for r̅=2, there can be two different models for r≤2 and four different models for r>2, as shown in FIG. 27, and described in the following:

### Rank 1 & 2:

Layer A1 AE (used for layer 1 in rank 1 and 2 transmissions)
Layer A2 AE (used for layer 2 in rank 1 and 2 transmissions)

### Rank 3 & 4:

Layer B1 AE (used for layer 1 in rank 3 and 4 transmissions)
Layer B2 AE (used for layer 2 in rank 3 and 4 transmissions)
Layer B3 AE (used for layer 3 in rank 3 and 4 transmissions)
Layer B4 AE (used for layer 4 in rank 3 and 4 transmissions)

FIG. 27 shows a layer specific and rank dependent/independent approach for r̅=2, resulting in a total of six models. For r≤2, the AEs are trained separately for each layer, where the UE generate n_{b}qᵣ feedback bits per layer. Similarly, for r>2, the AEs are trained separately for each layer, where the UE generate [n_{b}/r̅]qᵣ feedback bits per layer.

In the “Evaluation for rank>1” section below, the evaluation for the model in the above example, which shows the advantage of the proposed methods over the legacy Rel-16 Type-II CSI feedback (Reference [1]) is presented. Note that similar advantages can be achieved for other r>1 models, depending how well the AE is designed and trained.

### Embodiments for Explicit Configuration of Layer Information Processing

In the following embodiments, various methods allowing an explicit configuration for layer information processing are discussed, when the estimated rank is r>1. Such configuration can be signaled with RRC messaging, the DCI or the UCI. The methods provide additional flexibility to the network and/or the UE for dynamic configuration of the mapping between the feedback bits and the layer information. Note that although the description emphasizes the cases where the rank is larger than 1, the methods can also readily be applied when the UE reports CSI with RI=1. Further, in the following description the term latent space refers to the output layer of the encoder and latent space coefficients refers to the output from the neurons at the UE encoder.

Embodiments for configuration of latent space for AE model—In one embodiment, the gNB and the UE will initially agree on the procedure that the UE follows to select the latent space coefficients (i.e., the output from the neurons at the UE encoder) that will be quantized and transmitted to the gNB. In some embodiments, one or more of these procedures may be provided in specification text, and/or they may be agreed explicitly (e.g., by indicating the specific latent coefficient selection procedure selected when executing a given model) or implicitly (e.g., by associating a latent coefficient selection procedure to a given model) via over-the-air signaling or bilateral vendor agreements. For instance, some embodiments may describe in the specification text that only the outputs from the first N neurons should be quantized and sent back to the gNB.

In some embodiments, the gNB and the UE will agree on the number of latent space coefficients N that the UE feeds back to the gNB. Such number may be layer-dependent and/or rank-dependent.
In some embodiments, the number of latent space coefficients that can be fed back may be limited to a fixed set of values (e.g., only multiples of two latent coefficients may be allowed). This may both facilitate the signaling—reducing the overhead—and the AI/ML encoder model training time.
   In some embodiments, such fixed set of values may be UE-specific and selected by the UE from a set of allowed values provided by the specification. A given UE may communicate to the gNB the specific set of values allowed for such UE via, e.g., a field in the RRC UE capability information.
In some embodiments, the gNB will indicate the UE the number of latent space coefficients that the UE should fed back to the gNB. Such indication (which may be a recommendation or enforcement) may be explicit (e.g., by indicating the number of latent space coefficients that the UE should feed back to the gNB) or implicit (e.g., it may be determined by the number of time/frequency resource elements allocated for UCI, the recommended Modulation and Coding Scheme (MCS) for those resources, and the number of bits used to quantize each latent space coefficient). Such indication may be performed, e.g., via DCI or RRC.
In some embodiments, the UE will indicate to the gNB (i.e., within the UCI) the number of latent space coefficients fed back to the gNB.
In some embodiments, the gNB and/or the UE will indicate the offset number (positive or negative) of latent space coefficients with respect to a previously agreed baseline number.

Embodiments for configuration of quantization bits for AE model—In some embodiments, the gNB and the UE will agree on the number of bits that the UE utilizes to quantize each latent space coefficient. Such number may be layer-dependent and/or rank-dependent.
In some embodiments where the number of latent space coefficients that the UE feeds back to the gNB is agreed, such signaling may be implicit, e.g., there may be a pre-agreement between gNB and the UE on the number of bits per latent space coefficient and the number of latent space coefficients requested to be fed back may be directly determined by the number of time/frequency resource elements allocated for UCI and the recommended MCS for those resources.
In some embodiments, the UE will indicate to the gNB (i.e., within the UCI) the number of bits used to quantize the latent space coefficient fed back to the gNB. Such indication could be layer- and/or rank-dependent. Furthermore, the indication could be defined such that the number of quantization bits for layer X (say 2-bits with four possible quantization levels), is signaled relative to a previous layer, e.g. layer X−1 (say 1-bit indicating same or one less bit used for quantization), to reduce required signaling.
In some embodiments, the gNB and/or the UE will indicate the offset number (positive or negative) of quantization bits per latent space coefficients with respect to a previously agreed baseline number.

Embodiments for configuration of maximum quantization bits for latent space coefficients—In one embodiment, the maximum number of quantization bits per neuron Q_{B} at the bottleneck layer of the encoder:
is pre-defined for the AE model. In such embodiment, the UE may communicate to the gNB such capability, e.g., when responding to a gNB-sent UECapabilityEnquiry RRC message with a UECapabilityInformation RRC message. The capability may
   be sent explicitly in the UECapabilityInformation RRC message, or
   be sent implicitly in the sense that the UECapabilityInformation RRC message contains a model id based on which the gNB may look up, or derive, the information.
may be bounded by the specification.
is configured by the gNB depending on the AE model information, e.g., the Model ID,
   along with the UCI overhead for CSI reporting and signaled to the UE on DCI.
   through RRC signaling.

The gNB can configure Q_{B} such that Q_{B}≤Qₘₐₓ, where Qₘₐₓ is the maximum quantization bits per neuron that the AE model can process as provided by the AE model information. In addition, in determining the value of Q_{B}, the gNB may also consider that i) the AE model may have a minimum number of quantization bits per neuron, Qₘᵢₙ, such that Q_{B}≥Qₘᵢₙ, and/or ii) the number of quantization bits used during the training phase, Qₜᵣₐᵢₙ, which may be a single number of a lit of numbers if the AE is trained for multiple quantization levels. The gNB may choose Q_{B}≤Qₜᵣₐᵢₙ or choose Q_{B} as one of the entries in the list of trained quantization levels Qₜᵣₐᵢₙ.

In one implementation, it is possible that the NW may configure the UE with the size of the CSI report instead of Q_{B}. In this case, the UE may derive the value of Q_{B} based on the configured CSI report size and the value of n_{b}. The configured CSI report size may, for example, represent the CSI report size for the case of the UE reports CSI with rank 1. In another example, the configured CSI report size may represent the CSI report size for the case of the UE reports CSI with maximum rank, i.e., the same with the configured layer.

In another embodiment, instead of configured by the NW, the value of Q_{B} may also be determined by the UE, and be informed to the NW, e.g., together with the RI. To limit the size of the CSI feedback and/or to guarantee the accuracy of the CSI report, the NW may (instead of Q_{B}), configure the UE with Q_{B_max} and/or Q_{B_min}, where Q_{B_max} and Q_{B_min} are the maximum Q_{B} value that can be used by the UE and the minimum Q_{B} value that can be used by the UE, respectively. In some embodiments, such configuration may be performed via DCI and/or via RRC signaling. In some embodiments, the set of allowed values for Q_{B_max} and Q_{B_min} may be provided in the specification. In some embodiments, the set of allowed values for Q_{B_max} and Q_{B_min} for a given model is provided to the network by UE capability signaling, by bilateral agreement between vendors, or through other type of control signaling between the UE and network node. Alternatively, the UE may be configured with several possible value of Q_{B}, from which the UE can select one of the values to be used in the CSI report.

Embodiments for CQI computation based on the configuration of quantization bits for AE model—In some embodiments, the UE will calculate the CQI to be reported back to the gNB independently of the configuration of quantization bits for AE model. In other embodiments, the CQI reported back to the gNB will be dependent on the selected configuration of quantization bits for the AE model. For instance, UEs may apply a fixed offset to the SINR/CQI computed prior to compression and quantization, with such offset being implementation-specific in some embodiments and provided or limited by the specification in others.

Evaluation for rank>1

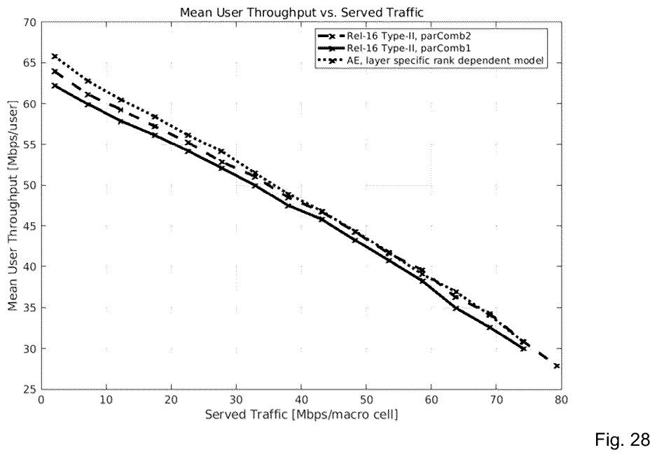

FIG. 28 illustrates the advantage of the proposed solution with the model described in FIG. 27, i.e., a layer specific and rank dependent AE model. In this evaluation, the gNB is equipped with a uniform planar array with N_{TX}=32 antenna ports and transmitting over N₃=52 RBs to UEs with N_{RX}=4 antenna port, such that the transmission rank per UE is bounded by r≤4. Further assuming that CSI-RS ports are non-beamformed so that each antenna port transmits one CSI-RS port. According, at a single time-instance, the antenna-frequency domain ‘raw’ channel H have a dimension of 32×52×4 (N_{TX}×N₃×N_{RX}). Subsequently, depending on the estimated rank r∈{1, 2, 3, 4}, the transmit covariance matrix is computed for H by averaging the covariance over the consecutive 4 RBs, followed by the extraction of the eigenvectors per layer, denoted by e_{r,l}_{ᵣ}, lᵣ=1, 2, . . . , r≤4, where the eigenvectors across the frequency units and the layers have a dimension of 32×13×r (N_{TX}×(N₃/4)×r).

Each eigenvector is pre-processed with L=4 Spatial-Domain (SD) basis per polarization and M=4 FD basis, which corresponds to parameter combination 5 (parComb5) (L=4, pᵥ=0.25) for Rel-16 Type-II pre-processing (Reference [1]). Depending on the estimated rank r, the resultant linear combination coefficient W₂, with dimension of 8×4×r, is compressed and quantized at the encoder per layer. The training data set consists of unquantized W₂ from the Rel-16 Type-II based pre-processing, where the AE is trained to minimize the Normalized Mean Square Error (NMSE) of the reconstructed W₂ across the layers for the estimated rank. With the layer specific and rank dependent model, half of the encoder output for r>2 is punctured (the activations from every second bottleneck-layer neuron are discarded by the UE). Accordingly, the AE is trained separately for r≤2 and r>2, resulting in six different trained AEs, which are used in the inference stage. Finally, depending on the r, the bits are feedback to the gNB along with the RI. With n_{b}=10 and qᵣ=4, for,
RI=1, the gNB can process all the 40 feedback bits for layer 1.
RI=2, the gNB can process the first 40 feedback bits for layer 1 and the final 40 feedback bits for layer 2.
RI=3, the gNB can process the first 20 feedback bits for layer 1, the next 20 feedback bits for layer 2, and the final 20 bits for layer 3.
RI=4, the gNB can process the first 20 feedback bits for layer 1, the next 20 feedback bits for layer 2, the next 20 bits for layer 3, and the final 20 bits for layer 4

Thus, FIG. 28 shows the mean user throughput vs served traffic performance for the layer specific and rank dependent AE model with the legacy Rel-16 Type-II with different parameter combination (parComb) as the baseline for r≥1 transmission. The evaluation was done with 7 sites and 10000 UEs in a Umi scenario.

Along with the overhead to signal the SD coefficients across the layers and FD coefficients per layer, the overhead for the AE is 63, 111, 99 and 127 bits for rank 1, 2, 3 and 4, respectively, which is comparable with Rel-16 Type-II parComb1 (L=2, β=0.25, and pᵥ=0.25 and 0.125 for r={1, 2} and r={3,4}, respectively) with overhead reduction compared to Rel-16 Type-II parComb2 (L=2, μ=0.50, and pᵥ=0.25 and 0.125 for r={1, 2} and r={3,4}, respectively). Note that the overhead for Rel-16 Type-II ParComb1 is 62, 113, 100 and 111 bits for rank 1, 2, 3 and 4, respectively. Similarly, the overhead for Rel-16 Type-II ParComb2 is 91, 169, 156 and 167 bits for rank 1, 2, 3 and 4, respectively. The proposed method has a throughput gain of around 3 to 5% gain over parComb1 and 30-40% overhead reduction over parComb2, depending on the traffic load.

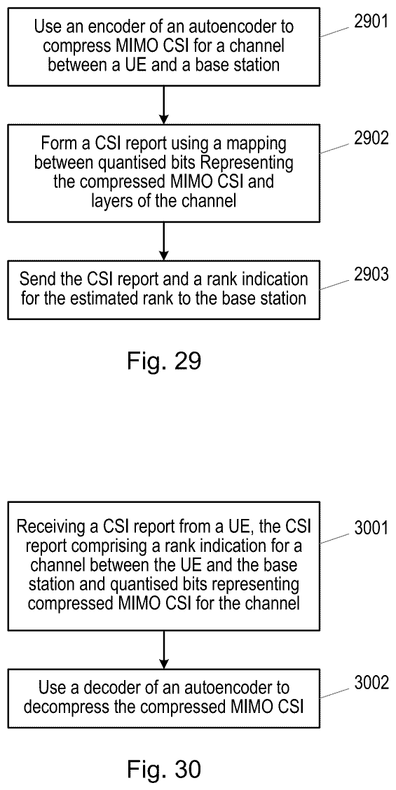

FIG. 29 is a flow chart illustrating a method according to various embodiments performed by a UE. The UE may perform the method in response to executing suitably formulated computer readable code. The computer readable code may be embodied or stored on a computer readable medium, such as a memory chip, optical disc, or other storage medium. The computer readable medium may be part of a computer program product.

In step 2901, the UE uses an encoder of an autoencoder to compress MIMO CSI for a channel between the UE and a base station.

In step 2902, the UE forms a CSI report using a mapping between quantised bits representing the compressed MIMO CSI and layers of the channel. The mapping is dependent on an estimated rank for the channel and/or a layer order. A layer of the channel is a data stream transmitted from the base station (e.g. gNB). Multiple layers denote multiple data streams (spatial multiplexing). The layers are transmitted from the gNB using different ‘generalized beams’ represented by different precoders. The precoders can be the eigenvector of the downlink channel, or some function of the eigenvectors. In this disclosure, the layer information is considered to be extracted from the estimated CSI at the UE, which can be eigenvectors or some pre-processed eigenvectors, then compressed at the encoder and fed back to the gNB.

In step 2903, the UE sends the CSI report and a rank indication for the estimated rank to the base station.

The mapping used in step 2902 may be defined in a 3GPP Standard Specification. In other embodiments, the UE sends a mapping indication to the base station that comprises an indication of the mapping used by the UE to form the CSI report. In other embodiments, the UE receives a mapping indication from the base station that comprises an indication of the mapping to use to form the CSI report. The mapping indication may be a suggested mapping option, and the UE can determine a mapping to use to form the CSI report from the suggested mapping option and at least one other mapping option. Alternatively the mapping indication can be an enforced mapping that the UE is required to use.

The CSI report formed in step 2902 may comprise the quantised bits concatenated across all layers of the channel according to the layer order.

The quantised bits may be output by the encoder of the autoencoder at the UE. Alternatively, compressed MIMO CSI is output by the encoder of the autoencoder at the UE, and the method further comprises the UE, prior to forming the CSI report, quantising the compressed MIMO CSI. In another alternative, compressed MIMO CSI is output by the autoencoder at the UE, and the method further comprises the UE, prior to forming the CSI report, quantising a subset of the output compressed MIMO CSI corresponding to selected neurons of the encoder of the autoencoder. In this alternative, the subset can be determined based on one or more of: layer; the estimated rank; UE capability information; RRC signalling; an indication received from the base station; DCI; a number of time and/or frequency resource elements allocated for UCI; and an active encoder model used by the UE.

The UE may send an indication to the base station of a number of quantised bits sent in the CSI report. Alternatively, the UE can receive an indication of a number of quantised bits to be sent in the CSI report from the base station.

The method performed by the UE may further comprise the UE receiving, from the base station, downlink reference signals (RS) for the channel, and a CSI reporting payload size. The downlink reference signals may comprise one or both of: CSI-RS and DMRS. The method performed by the UE may further comprise the UE determining the CSI based on the received downlink reference signals.

The method performed by the UE can further comprise the UE determining the rank indication based on the MIMO CSI.

The MIMO CSI that is input into the encoder of the autoencoder may comprise eigenvectors for each layer of the channel.

The method performed by the UE may further comprise the UE, prior to step 2901, pre-processing the MIMO CSI. The pre-processing may be based on the rank indication. Pre-processing can comprise one or more of the following steps: (i) performing spatial-domain DFT per layer to transform the MIMO CSI from antenna-frequency domain to beam-frequency domain and selecting a set of beams; (ii) obtaining an eigenvector for each layer of the channel; and (iii) performing frequency-domain DFT per layer to transform the eigenvectors from antenna/beam-frequency domain to antenna/beam-delay domain and selecting a set of taps. The pre-processing may further comprise extracting features of the eigenvectors per layer in the beam-delay domain.

The layer order may indicate that the layers are to be ordered by decreasing eigenvalue.

The method performed by the UE may further comprise the UE receiving a quantization indication from the base station that comprises an indication of a maximum number, Q_{B}, of quantised bits per neuron of the autoencoder output to be used for determining the CSI report.

The method performed by the UE may further comprise the UE transmitting a quantization indication to the base station that comprises an indication of a maximum number, Q_{B}, of quantised bits per neuron of the output of the encoder of the autoencoder to be used for determining the CSI report.

The mapping may indicate a number of quantised bits per neuron of the output of the encoder of the autoencoder as a function of channel layer based on the layer order.

The mapping for a given channel layer may be independent of the estimated rank for the channel.

The number of quantised bits per neuron of the output of the encoder of the autoencoder may decrease with decreasing channel layer eigenvalue.

Alternatively, the mapping can indicate a number of quantised bits per neuron of the output of the encoder of the autoencoder as a function of the estimated rank for the channel. The mapping for a given estimated rank may be independent of the channel layer. The number of quantised bits per neuron of the output of the encoder of the autoencoder can decrease with increasing rank.

Alternatively, the mapping can indicate a number of quantised bits per neuron of the output of the encoder of the autoencoder as a function of the estimated rank for the channel and order of the corresponding channel layers. The number of quantised bits per neuron of the output of the encoder of the autoencoder can decrease with increasing rank.

In another alternative, the mapping can indicate a set of pre-determined values corresponding to the number of quantised bits for each neuron of the output of the encoder of the autoencoder, and the pre-determined values depend on a total number of channel layers and/or a total number of neurons of the encoder of the autoencoder.

FIG. 30 is a flow chart illustrating a method according to various embodiments performed by a base station, such as a gNB. The base station (gNB) may perform the method in response to executing suitably formulated computer readable code. The computer readable code may be embodied or stored on a computer readable medium, such as a memory chip, optical disc, or other storage medium. The computer readable medium may be part of a computer program product.

In step 3001, the base station receives a CSI report from a UE. The CSI report comprises quantised bits representing compressed MIMO CSI for a channel between the UE and the base station, and a rank indication for the channel.

In step 3002, the base station uses a decoder of an autoencoder to decompress the compressed MIMO CSI based on (i) the rank indication and (ii) a mapping between quantised bits representing the compressed MIMO CSI and layers of the channel. The mapping is dependent on an estimated rank for the channel and/or a layer order.

Step 3002 may comprise determining an eigenvector for each layer of the channel.

The method may further include the step of the base station determining multi-user MIMO precoders for each layer of the channel based on the result of step 3002. The base station may then perform transmissions on the channel using the determined precoders. These transmissions may be performed on the PDSCH.

The mapping used in step 3002 may be defined in a 3GPP Standard Specification. In other embodiments, the base station receives a mapping indication from the UE that comprises an indication of the mapping used by the UE to form the CSI report. In other embodiments, the base station sends a mapping indication to the UE that comprises an indication of the mapping to use to form the CSI report. The mapping indication may be a suggested mapping option, or an enforced mapping that the UE is required to use.

The CSI report received in step 3001 may comprise the quantised bits concatenated across all layers of the channel according to the layer order.

The base station may receive an indication from the UE of a number of quantised bits sent in the CSI report.

Alternatively, the base station can send an indication to the UE of a number of quantised bits to be sent in the CSI report.

The method performed by the base station may further comprise the base station sending, to the UE, downlink reference signals (RS) for the channel, and a CSI reporting payload size. The downlink reference signals may comprise one or both of: CSI-RS and DMRS.

The layer order may indicate that the layers are to be ordered by decreasing eigenvalue.

The method performed by the base station may further comprise the base station sending a quantization indication to the UE that comprises an indication of a maximum number, Q_{B}, of quantised bits per neuron of the autoencoder output to be used for determining the CSI report.

The method performed by the base station may further comprise the base station receiving a quantization indication from the UE that comprises an indication of a maximum number, Q_{B}, of quantised bits per neuron of the output of the encoder of the autoencoder to be used for determining the CSI report.

The mapping may indicate a number of quantised bits per neuron of the output of the encoder of the autoencoder as a function of channel layer based on the layer order.

The mapping for a given channel layer may be independent of the estimated rank for the channel.

The number of quantised bits per neuron of the output of the encoder of the autoencoder may decrease with decreasing channel layer eigenvalue.

Alternatively, the mapping can indicate a number of quantised bits per neuron of the output of the encoder of the autoencoder as a function of the estimated rank for the channel. The mapping for a given estimated rank may be independent of the channel layer. The number of quantised bits per neuron of the output of the encoder of the autoencoder can decrease with increasing rank.

Alternatively, the mapping can indicate a number of quantised bits per neuron of the output of the encoder of the autoencoder as a function of the estimated rank for the channel and order of the corresponding channel layers. The number of quantised bits per neuron of the output of the encoder of the autoencoder can decrease with increasing rank.

In another alternative, the mapping can indicate a set of pre-determined values corresponding to the number of quantised bits for each neuron of the output of the encoder of the autoencoder, and the pre-determined values depend on a total number of channel layers and/or a total number of neurons of the encoder of the autoencoder.

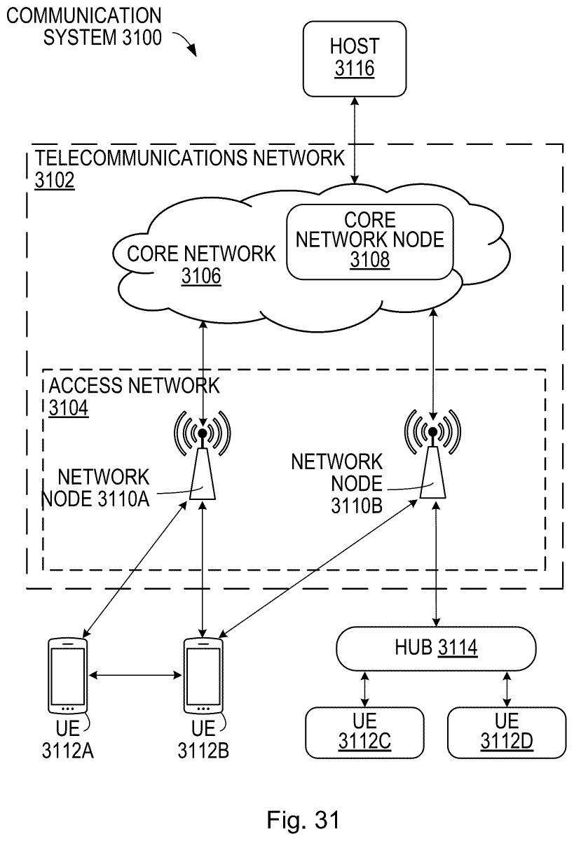

FIG. 31 shows an example of a communication system 3100 in accordance with some embodiments. In the example, the communication system 3100 includes a telecommunication network 3102 that includes an access network 3104, such as a radio access network (RAN), and a core network 3106, which includes one or more core network nodes 3108. The access network 3104 includes one or more access network nodes, such as access network nodes 3110a and 3110b (one or more of which may be generally referred to as access network nodes 3110), or any other similar 3^{rd} Generation Partnership Project (3GPP) access node or non-3GPP access point. The access network nodes 3110 facilitate direct or indirect connection of wireless devices (also referred to interchangeably herein as user equipment (UE)), such as by connecting UEs 3112a, 3112b, 3112c, and 3112d (one or more of which may be generally referred to as UEs 3112) to the core network 3106 over one or more wireless connections. The access network nodes 3110 may be, for example, access points (APs) (e.g. radio access points), base stations (BSs) (e.g. radio base stations, Node Bs, evolved Node Bs (eNBs) and NR NodeBs (gNBs)).

Example wireless communications over a wireless connection include transmitting and/or receiving wireless signals using electromagnetic waves, radio waves, infrared waves, and/or other types of signals suitable for conveying information without the use of wires, cables, or other material conductors. Moreover, in different embodiments, the communication system 3100 may include any number of wired or wireless networks, network nodes, UEs, and/or any other components or systems that may facilitate or participate in the communication of data and/or signals whether via wired or wireless connections. The communication system 3100 may include and/or interface with any type of communication, telecommunication, data, cellular, radio network, and/or other similar type of system.

The wireless devices/UEs 3112 may be any of a wide variety of communication devices, including wireless devices arranged, configured, and/or operable to communicate wirelessly with the network nodes 3110 and other communication devices. Similarly, the access network nodes 3110 are arranged, capable, configured, and/or operable to communicate directly or indirectly with the UEs 3112 and/or with other network nodes or equipment in the telecommunication network 3102 to enable and/or provide network access, such as wireless network access, and/or to perform other functions, such as administration in the telecommunication network 3102.

The core network 3106 includes one more core network nodes (e.g. core network node 3108) that are structured with hardware and software components. Features of these components may be substantially similar to those described with respect to the wireless devices/UEs, access network nodes, such that the descriptions thereof are generally applicable to the corresponding components of the core network node 3108. Example core network nodes include functions of one or more of a Mobile Switching Center (MSC), Mobility Management Entity (MME), Home Subscriber Server (HSS), Access and Mobility Management Function (AMF), Session Management Function (SMF), Authentication Server Function (AUSF), Subscription Identifier De-concealing function (SIDF), Unified Data Management (UDM), Security Edge Protection Proxy (SEPP), Network Exposure Function (NEF), and/or a User Plane Function (UPF).

As a whole, the communication system 3100 of FIG. 31 enables connectivity between the wireless devices/UEs, network nodes. In that sense, the communication system may be configured to operate according to predefined rules or procedures, such as specific standards that include, but are not limited to: Global System for Mobile Communications (GSM); Universal Mobile Telecommunications System (UMTS); Long Term Evolution (LTE), and/or other suitable 2G, 3G, 4G, 5G standards, or any applicable future generation standard (e.g. 6G); wireless local area network (WLAN) standards, such as the Institute of Electrical and Electronics Engineers (IEEE) 802.11 standards (WiFi); and/or any other appropriate wireless communication standard, such as the Worldwide Interoperability for Microwave Access (WiMax), Bluetooth, Z-Wave, Near Field Communication (NFC) ZigBee, LiFi, and/or any low-power wide-area network (LPWAN) standards such as LoRa and Sigfox.

In some examples, the telecommunication network 3102 is a cellular network that implements 3GPP standardized features. Accordingly, the telecommunications network 3102 may support network slicing to provide different logical networks to different devices that are connected to the telecommunication network 3102. For example, the telecommunications network 3102 may provide Ultra Reliable Low Latency Communication (URLLC) services to some UEs, while providing Enhanced Mobile Broadband (eMBB) services to other UEs, and/or Massive Machine Type Communication (mMTC)/Massive Internet of Things (IoT) services to yet further UEs.

In some examples, the UEs 3112 are configured to transmit and/or receive information without direct human interaction. For instance, a UE may be designed to transmit information to the access network 3104 on a predetermined schedule, when triggered by an internal or external event, or in response to requests from the access network 3104. Additionally, a UE may be configured for operating in single- or multi-Radio Access Technology (RAT) or multi-standard mode. For example, a UE may operate with any one or combination of Wi-Fi, NR (New Radio) and LTE, i.e. being configured for multi-radio dual connectivity (MR-DC), such as E-UTRAN (Evolved-UMTS Terrestrial Radio Access Network) New Radio-Dual Connectivity (EN-DC).

In the example illustrated in FIG. 31, the hub 3114 communicates with the access network 3104 to facilitate indirect communication between one or more UEs (e.g. UE 3112c and/or 3112d) and access network nodes (e.g. access network node 3110b). In some examples, the hub 3114 may be a controller, router, a content source and analytics node, or any of the other communication devices described herein regarding UEs. For example, the hub 3114 may be a broadband router enabling access to the core network 3106 for the UEs. As another example, the hub 3114 may be a controller that sends commands or instructions to one or more actuators in the UEs. Commands or instructions may be received from the UEs, network nodes 3110, or by executable code, script, process, or other instructions in the hub 3114. As another example, the hub 3114 may be a data collector that acts as temporary storage for UE data and, in some embodiments, may perform analysis or other processing of the data. As another example, the hub 3114 may be a content source. For example, for a UE that is a VR headset, display, loudspeaker or other media delivery device, the hub 3114 may retrieve VR assets, video, audio, or other media or data related to sensory information via a network node, which the hub 3114 then provides to the UE either directly, after performing local processing, and/or after adding additional local content. In still another example, the hub 3114 acts as a proxy server or orchestrator for the UEs, in particular in if one or more of the UEs are low energy IoT devices.

The hub 3114 may have a constant/persistent or intermittent connection to the network node 3110b. The hub 3114 may also allow for a different communication scheme and/or schedule between the hub 3114 and UEs (e.g. UE 3112c and/or 3112d), and between the hub 3114 and the core network 3106. In other examples, the hub 3114 is connected to the core network 3106 and/or one or more UEs via a wired connection. Moreover, the hub 3114 may be configured to connect to an M2M service provider over the access network 3104 and/or to another UE over a direct connection. In some scenarios, UEs may establish a wireless connection with the network nodes 3110 while still connected via the hub 3114 via a wired or wireless connection. In some embodiments, the hub 3114 may be a dedicated hub—that is, a hub whose primary function is to route communications to/from the UEs from/to the network node 3110b. In other embodiments, the hub 3114 may be a non-dedicated hub—that is, a device which is capable of operating to route communications between the UEs and network node 3110b, but which is additionally capable of operating as a communication start and/or end point for certain data channels.

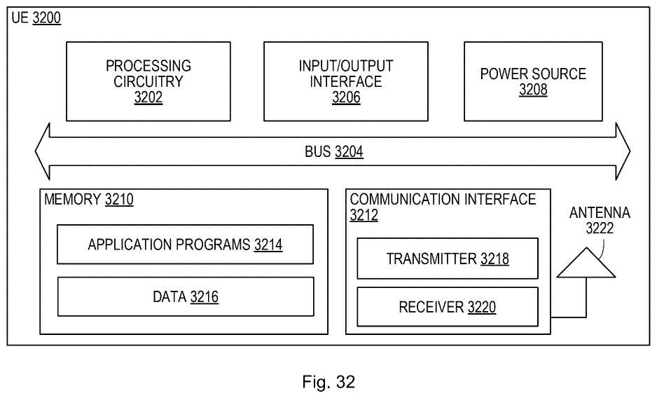

FIG. 32 shows a wireless device or UE 3200 in accordance with some embodiments. As used herein, a UE refers to a device capable, configured, arranged and/or operable to communicate wirelessly with network nodes and/or other UEs. Examples of a wireless device/UE include, but are not limited to, a smart phone, mobile phone, cell phone, voice over IP (VoIP) phone, wireless local loop phone, desktop computer, personal digital assistant (PDA), wireless camera, gaming console or device, music storage device, playback appliance, wearable terminal device, wireless endpoint, mobile station, tablet, laptop, laptop-embedded equipment (LEE), laptop-mounted equipment (LME), smart device, wireless customer-premise equipment (CPE), vehicle-mounted or vehicle embedded/integrated wireless device, etc. Other examples include any UE identified by the 3rd Generation Partnership Project (3GPP), including a narrow band internet of things (NB-IoT) UE, a machine type communication (MTC) UE, and/or an enhanced MTC (eMTC) UE.

A wireless device/UE may support device-to-device (D2D) communication, for example by implementing a 3GPP standard for sidelink communication, Dedicated Short-Range Communication (DSRC), vehicle-to-vehicle (V2V), vehicle-to-infrastructure (V2I), or vehicle-to-everything (V2X). In other examples, a UE may not necessarily have a user in the sense of a human user who owns and/or operates the relevant device. Instead, a UE may represent a device that is intended for sale to, or operation by, a human user but which may not, or which may not initially, be associated with a specific human user (e.g. a smart sprinkler controller). Alternatively, a UE may represent a device that is not intended for sale to, or operation by, an end user but which may be associated with or operated for the benefit of a user (e.g. a smart power meter).

The UE 3200 includes processing circuitry 3202 that is operatively coupled via a bus 3204 to an input/output interface 3206, a power source 3208, a memory 3210, a communication interface 3212, and/or any other component, or any combination thereof. Certain UEs may utilize all or a subset of the components shown in FIG. 32. The level of integration between the components may vary from one UE to another UE. Further, certain UEs may contain multiple instances of a component, such as multiple processors, memories, transceivers, transmitters, receivers, etc.

The processing circuitry 3202 is configured to process instructions and data and may be configured to implement any sequential state machine operative to execute instructions stored as machine-readable computer programs in the memory 3210. The processing circuitry 3202 may be implemented as one or more hardware-implemented state machines (e.g. in discrete logic, field-programmable gate arrays (FPGAs), application specific integrated circuits (ASICs), etc.); programmable logic together with appropriate firmware; one or more stored computer programs, general-purpose processors, such as a microprocessor or digital signal processor (DSP), together with appropriate software; or any combination of the above. For example, the processing circuitry 3202 may include multiple central processing units (CPUs). The processing circuitry 3202 may be operable to provide, either alone or in conjunction with other UE 3200 components, such as the memory 3210, to provide UE 3200 functionality. For example, the processing circuitry 3202 may be configured to cause the UE 3202 to perform the methods as described with reference to FIG. 29.

In the example, the input/output interface 3206 may be configured to provide an interface or interfaces to an input device, output device, or one or more input and/or output devices. Examples of an output device include a speaker, a sound card, a video card, a display, a monitor, a printer, an actuator, an emitter, a smartcard, another output device, or any combination thereof. An input device may allow a user to capture information into the UE 3200. Examples of an input device include a touch-sensitive or presence-sensitive display, a camera (e.g. a digital camera, a digital video camera, a web camera, etc.), a microphone, a sensor, a mouse, a trackball, a directional pad, a trackpad, a scroll wheel, a smartcard, and the like. The presence-sensitive display may include a capacitive or resistive touch sensor to sense input from a user. A sensor may be, for instance, an accelerometer, a gyroscope, a tilt sensor, a force sensor, a magnetometer, an optical sensor, a proximity sensor, a biometric sensor, etc., or any combination thereof. An output device may use the same type of interface port as an input device. For example, a Universal Serial Bus (USB) port may be used to provide an input device and an output device.

In some embodiments, the power source 3208 is structured as a battery or battery pack. Other types of power sources, such as an external power source (e.g. an electricity outlet), photovoltaic device, or power cell, may be used. The power source 3208 may further include power circuitry for delivering power from the power source 3208 itself, and/or an external power source, to the various parts of the UE 3200 via input circuitry or an interface such as an electrical power cable. Delivering power may be, for example, for charging of the power source 3208. Power circuitry may perform any formatting, converting, or other modification to the power from the power source 3208 to make the power suitable for the respective components of the UE 3200 to which power is supplied.

The memory 3210 may be or be configured to include memory such as random access memory (RAM), read-only memory (ROM), programmable read-only memory (PROM), erasable programmable read-only memory (EPROM), electrically erasable programmable read-only memory (EEPROM), magnetic disks, optical disks, hard disks, removable cartridges, flash drives, and so forth. In one example, the memory 3210 includes one or more application programs 3214, such as an operating system, web browser application, a widget, gadget engine, or other application, and corresponding data 3216. The memory 3210 may store, for use by the UE 3200, any of a variety of various operating systems or combinations of operating systems.

The memory 3210 may be configured to include a number of physical drive units, such as redundant array of independent disks (RAID), flash memory, USB flash drive, external hard disk drive, thumb drive, pen drive, key drive, high-density digital versatile disc (HD-DVD) optical disc drive, internal hard disk drive, Blu-Ray optical disc drive, holographic digital data storage (HDDS) optical disc drive, external mini-dual in-line memory module (DIMM), synchronous dynamic random access memory (SDRAM), external micro-DIMM SDRAM, smartcard memory such as tamper resistant module in the form of a universal integrated circuit card (UICC) including one or more subscriber identity modules (SIMs), such as a Universal SIM (USIM) and/or Integrated SIM (ISIM), other memory, or any combination thereof. The UICC may for example be an embedded UICC (eUICC), integrated UICC (iUICC) or a removable UICC commonly known as ‘SIM card.’ The memory 3210 may allow the UE 3200 to access instructions, application programs and the like, stored on transitory or non-transitory memory media, to off-load data, or to upload data. An article of manufacture, such as one utilizing a communication system may be tangibly embodied as or in the memory 3210, which may be or comprise a device-readable storage medium.

The processing circuitry 3202 may be configured to communicate with an access network or other network using the communication interface 3212. The communication interface 3212 may comprise one or more communication subsystems and may include or be communicatively coupled to an antenna 3222. The communication interface 3212 may include one or more transceivers used to communicate, such as by communicating with one or more remote transceivers of another device capable of wireless communication (e.g. another UE or a network node in an access network). Each transceiver may include a transmitter 3218 and/or a receiver 3220 appropriate to provide network communications (e.g. optical, electrical, frequency allocations, and so forth). Moreover, the transmitter 3218 and receiver 3220 may be coupled to one or more antennas (e.g. antenna 3222) and may share circuit components, software or firmware, or alternatively be implemented separately.

In some embodiments, communication functions of the communication interface 3212 may include cellular communication, Wi-Fi communication, LPWAN communication, data communication, voice communication, multimedia communication, short-range communications such as Bluetooth, near-field communication, location-based communication such as the use of the global positioning system (GPS) to determine a location, another like communication function, or any combination thereof. Communications may be implemented in according to one or more communication protocols and/or standards, such as IEEE 802.11, Code Division Multiplexing Access (CDMA), Wideband Code Division Multiple Access (WCDMA), GSM, LTE, New Radio (NR), UMTS, WiMax, Ethernet, transmission control protocol/internet protocol (TCP/IP), synchronous optical networking (SONET), Asynchronous Transfer Mode (ATM), QUIC, Hypertext Transfer Protocol (HTTP), and so forth.

Regardless of the type of sensor, a UE may provide an output of data captured by its sensors, through its communication interface 3212, via a wireless connection to a network node. Data captured by sensors of a UE can be communicated through a wireless connection to a network node via another UE. The output may be periodic (e.g. once every 15 minutes if it reports the sensed temperature), random (e.g. to even out the load from reporting from several sensors), in response to a triggering event (e.g. when moisture is detected an alert is sent), in response to a request (e.g. a user initiated request), or a continuous stream (e.g. a live video feed of a patient).

As another example, a UE comprises an actuator, a motor, or a switch, related to a communication interface configured to receive wireless input from a network node via a wireless connection. In response to the received wireless input the states of the actuator, the motor, or the switch may change. For example, the UE may comprise a motor that adjusts the control surfaces or rotors of a drone in flight according to the received input or controls a robotic arm performing a medical procedure according to the received input.

A UE, when in the form of an Internet of Things (IoT) device, may be a device for use in one or more application domains, these domains comprising, but not limited to, city wearable technology, extended industrial application and healthcare. Non-limiting examples of such an IoT device are devices which are or which are embedded in: a connected refrigerator or freezer, a TV, a connected lighting device, an electricity meter, a robot vacuum cleaner, a voice controlled smart speaker, a home security camera, a motion detector, a thermostat, a smoke detector, a door/window sensor, a flood/moisture sensor, an electrical door lock, a connected doorbell, an air conditioning system like a heat pump, an autonomous vehicle, a surveillance system, a weather monitoring device, a vehicle parking monitoring device, an electric vehicle charging station, a smart watch, a fitness tracker, a head-mounted display for Augmented Reality (AR) or Virtual Reality (VR), a wearable for tactile augmentation or sensory enhancement, a water sprinkler, an animal- or item-tracking device, a sensor for monitoring a plant or animal, an industrial robot, an Unmanned Aerial Vehicle (UAV), and any kind of medical device, like a heart rate monitor or a remote controlled surgical robot. A UE in the form of an IoT device comprises circuitry and/or software in dependence on the intended application of the IoT device in addition to other components as described in relation to the UE 3200 shown in FIG. 32.

As yet another specific example, in an IoT scenario, a UE may represent a machine or other device that performs monitoring and/or measurements, and transmits the results of such monitoring and/or measurements to another UE and/or a network node. The UE may in this case be an M2M device, which may in a 3GPP context be referred to as an MTC device. As one particular example, the UE may implement the 3GPP NB-IoT standard. In other scenarios, a UE may represent a vehicle, such as a car, a bus, a truck, a ship and an airplane, or other equipment that is capable of monitoring and/or reporting on its operational status or other functions associated with its operation.

In practice, any number of UEs may be used together with respect to a single use case. For example, a first UE might be or be integrated in a drone and provide the drone's speed information (obtained through a speed sensor) to a second UE that is a remote controller operating the drone. When the user makes changes from the remote controller, the first UE may adjust the throttle on the drone (e.g. by controlling an actuator) to increase or decrease the drone's speed. The first and/or the second UE can also include more than one of the functionalities described above. For example, a UE might comprise the sensor and the actuator, and handle communication of data for both the speed sensor and the actuators.

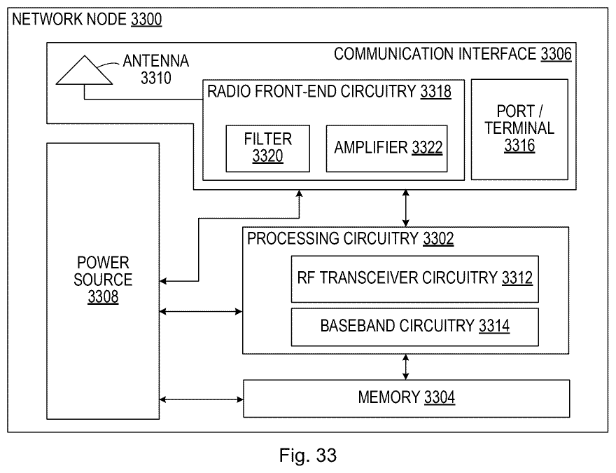

FIG. 33 shows a network node 3300 in accordance with some embodiments. As used herein, network node refers to equipment capable, configured, arranged and/or operable to communicate directly or indirectly with a UE and/or with other network nodes or equipment, in a telecommunication network. Examples of network nodes include, but are not limited to, access network nodes such as access points (APs) (e.g. radio access points), base stations (BSs) (e.g. radio base stations, Node Bs, evolved Node Bs (eNBs) and NR NodeBs (gNBs)).

Base stations may be categorized based on the amount of coverage they provide (or, stated differently, their transmit power level) and so, depending on the provided amount of coverage, may be referred to as femto base stations, pico base stations, micro base stations, or macro base stations. A base station may be a relay node or a relay donor node controlling a relay. A network node may also include one or more (or all) parts of a distributed radio base station such as centralized digital units and/or remote radio units (RRUs), sometimes referred to as Remote Radio Heads (RRHs). Such remote radio units may or may not be integrated with an antenna as an antenna integrated radio. Parts of a distributed radio base station may also be referred to as nodes in a distributed antenna system (DAS).

Other examples of network nodes include multiple transmission point (multi-TRP) 5G access nodes, multi-standard radio (MSR) equipment such as MSR BSs, network controllers such as radio network controllers (RNCs) or base station controllers (BSCs), base transceiver stations (BTSs), transmission points, transmission nodes, multi-cell/multicast coordination entities (MCEs), Operation and Maintenance (O&M) nodes, Operations Support System (OSS) nodes, Self-Organizing Network (SON) nodes, positioning nodes (e.g. Evolved Serving Mobile Location Centers (E-SMLCs)), and/or Minimization of Drive Tests (MDTs).

The network node 3300 includes processing circuitry 3302, a memory 3304, a communication interface 3306, and a power source 3308, and/or any other component, or any combination thereof. The network node 3300 may be composed of multiple physically separate components (e.g. a NodeB component and a RNC component, or a BTS component and a BSC component, etc.), which may each have their own respective components. In certain scenarios in which the network node 3300 comprises multiple separate components (e.g. BTS and BSC components), one or more of the separate components may be shared among several network nodes. For example, a single RNC may control multiple NodeBs. In such a scenario, each unique NodeB and RNC pair, may in some instances be considered a single separate network node. In some embodiments, the network node 3300 may be configured to support multiple radio access technologies (RATs). In such embodiments, some components may be duplicated (e.g. separate memory 3304 for different RATs) and some components may be reused (e.g. a same antenna 3310 may be shared by different RATs). The network node 3300 may also include multiple sets of the various illustrated components for different wireless technologies integrated into network node 3300, for example GSM, WCDMA, LTE, NR, WiFi, Zigbee, Z-wave, LoRaWAN, Radio Frequency Identification (RFID) or Bluetooth wireless technologies. These wireless technologies may be integrated into the same or different chip or set of chips and other components within network node 3300.

The processing circuitry 3302 may comprise a combination of one or more of a microprocessor, controller, microcontroller, central processing unit, digital signal processor, application-specific integrated circuit, field programmable gate array, or any other suitable computing device, resource, or combination of hardware, software and/or encoded logic operable to provide, either alone or in conjunction with other network node 3300 components, such as the memory 3304, to provide network node 3300 functionality. For example, the processing circuitry 3302 may be configured to cause the network node to perform the methods as described with reference to FIG. 30.

In some embodiments, the processing circuitry 3302 includes a system on a chip (SOC). In some embodiments, the processing circuitry 3302 includes one or more of radio frequency (RF) transceiver circuitry 3312 and baseband processing circuitry 3314. In some embodiments, the radio frequency (RF) transceiver circuitry 3312 and the baseband processing circuitry 3314 may be on separate chips (or sets of chips), boards, or units, such as radio units and digital units. In alternative embodiments, part or all of RF transceiver circuitry 3312 and baseband processing circuitry 3314 may be on the same chip or set of chips, boards, or units.

The memory 3304 may comprise any form of volatile or non-volatile computer-readable memory including, without limitation, persistent storage, solid-state memory, remotely mounted memory, magnetic media, optical media, random access memory (RAM), read-only memory (ROM), mass storage media (for example, a hard disk), removable storage media (for example, a flash drive, a Compact Disk (CD) or a Digital Video Disk (DVD)), and/or any other volatile or non-volatile, non-transitory device-readable and/or computer-executable memory devices that store information, data, and/or instructions that may be used by the processing circuitry 3302. The memory 3304 may store any suitable instructions, data, or information, including a computer program, software, an application including one or more of logic, rules, code, tables, and/or other instructions capable of being executed by the processing circuitry 3302 and utilized by the network node 3300. The memory 3304 may be used to store any calculations made by the processing circuitry 3302 and/or any data received via the communication interface 3306. In some embodiments, the processing circuitry 3302 and memory 3304 is integrated.

The communication interface 3306 is used in wired or wireless communication of signalling and/or data between network nodes, the access network, the core network, and/or a UE. As illustrated, the communication interface 3306 comprises port(s)/terminal(s) 3316 to send and receive data, for example to and from a network over a wired connection.

In embodiments, the communication interface 3306 also includes radio front-end circuitry 3318 that may be coupled to, or in certain embodiments a part of, the antenna 3310. Radio front-end circuitry 3318 comprises filters 3320 and amplifiers 3322. The radio front-end circuitry 3318 may be connected to an antenna 3310 and processing circuitry 3302. The radio front-end circuitry may be configured to condition signals communicated between antenna 3310 and processing circuitry 3302. The radio front-end circuitry 3318 may receive digital data that is to be sent out to other network nodes or UEs via a wireless connection. The radio front-end circuitry 3318 may convert the digital data into a radio signal having the appropriate channel and bandwidth parameters using a combination of filters 3320 and/or amplifiers 3322. The radio signal may then be transmitted via the antenna 3310. Similarly, when receiving data, the antenna 3310 may collect radio signals which are then converted into digital data by the radio front-end circuitry 3318. The digital data may be passed to the processing circuitry 3302. In other embodiments, the communication interface may comprise different components and/or different combinations of components.

In certain alternative embodiments, the access network node 3300 does not include separate radio front-end circuitry 3318, instead, the processing circuitry 3302 includes radio front-end circuitry and is connected to the antenna 3310. Similarly, in some embodiments, all or some of the RF transceiver circuitry 3312 is part of the communication interface 3306. In still other embodiments, the communication interface 3306 includes one or more ports or terminals 3316, the radio front-end circuitry 3318, and the RF transceiver circuitry 3312, as part of a radio unit (not shown), and the communication interface 3306 communicates with the baseband processing circuitry 3314, which is part of a digital unit (not shown).

The antenna 3310 may include one or more antennas, or antenna arrays, configured to send and/or receive wireless signals. The antenna 3310 may be coupled to the radio front-end circuitry 3318 and may be any type of antenna capable of transmitting and receiving data and/or signals wirelessly. In certain embodiments, the antenna 3310 is separate from the network node 3300 and connectable to the network node 3300 through an interface or port.

The antenna 3310, communication interface 3306, and/or the processing circuitry 3302 may be configured to perform any receiving operations and/or certain obtaining operations described herein as being performed by the network node. Any information, data and/or signals may be received from a UE, another network node and/or any other network equipment. Similarly, the antenna 3310, the communication interface 3306, and/or the processing circuitry 3302 may be configured to perform any transmitting operations described herein as being performed by the network node. Any information, data and/or signals may be transmitted to a UE, another network node and/or any other network equipment.

The power source 3308 provides power to the various components of network node 3300 in a form suitable for the respective components (e.g. at a voltage and current level needed for each respective component). The power source 3308 may further comprise, or be coupled to, power management circuitry to supply the components of the network node 3300 with power for performing the functionality described herein. For example, the network node 3300 may be connectable to an external power source (e.g. the power grid, an electricity outlet) via an input circuitry or interface such as an electrical cable, whereby the external power source supplies power to power circuitry of the power source 3308. As a further example, the power source 3308 may comprise a source of power in the form of a battery or battery pack which is connected to, or integrated in, power circuitry. The battery may provide backup power should the external power source fail.

Embodiments of the network node 3300 may include additional components beyond those shown in FIG. 33 for providing certain aspects of the network node's functionality, including any of the functionality described herein and/or any functionality necessary to support the subject matter described herein. For example, the network node 3300 may include user interface equipment to allow input of information into the network node 3300 and to allow output of information from the network node 3300. This may allow a user to perform diagnostic, maintenance, repair, and other administrative functions for the network node 3300.

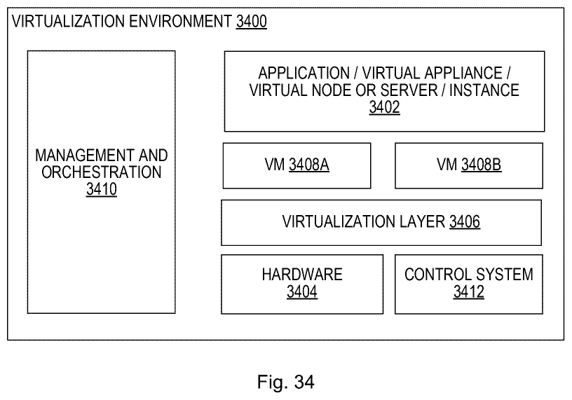

FIG. 34 is a block diagram illustrating a virtualization environment 3400 in which functions implemented by some embodiments may be virtualized. In the present context, virtualizing means creating virtual versions of apparatuses or devices which may include virtualizing hardware platforms, storage devices and networking resources. As used herein, virtualization can be applied to any device described herein, or components thereof, and relates to an implementation in which at least a portion of the functionality is implemented as one or more virtual components. Some or all of the functions described herein may be implemented as virtual components executed by one or more virtual machines (VMs) implemented in one or more virtual environments 3400 hosted by one or more of hardware nodes, such as a hardware computing device that operates as an access network node, a wireless device/UE, a core network node. Further, in embodiments in which the virtual node does not require radio connectivity (e.g. a core network node), then the node may be entirely virtualized.

Applications 3402 (which may alternatively be called software instances, virtual appliances, network functions, virtual nodes, virtual network functions, etc.) are run in the virtualization environment 3400 to implement some of the features, functions, and/or benefits of some of the embodiments disclosed herein.

Hardware 3404 includes processing circuitry, memory that stores software and/or instructions executable by hardware processing circuitry, and/or other hardware devices as described herein, such as a network interface, input/output interface, and so forth. Software may be executed by the processing circuitry to instantiate one or more virtualization layers 3406 (also referred to as hypervisors or virtual machine monitors (VMMs)), provide VMs 3408a and 3408b (one or more of which may be generally referred to as VMs 3408), and/or perform any of the functions, features and/or benefits described in relation with some embodiments described herein. The virtualization layer 3406 may present a virtual operating platform that appears like networking hardware to the VMs 3408.

The VMs 3408 comprise virtual processing, virtual memory, virtual networking or interface and virtual storage, and may be run by a corresponding virtualization layer 3406. Different embodiments of the instance of a virtual appliance 3402 may be implemented on one or more of VMs 3408, and the implementations may be made in different ways. Virtualization of the hardware is in some contexts referred to as network function virtualization (NFV). NFV may be used to consolidate many network equipment types onto industry standard high volume server hardware, physical switches, and physical storage, which can be located in data centers, and customer premise equipment.

In the context of NFV, a VM 3408 may be a software implementation of a physical machine that runs programs as if they were executing on a physical, non-virtualized machine. Each of the VMs 3408, and that part of hardware 3404 that executes that VM, be it hardware dedicated to that VM and/or hardware shared by that VM with others of the VMs, forms separate virtual network elements. Still in the context of NFV, a virtual network function is responsible for handling specific network functions that run in one or more VMs 3408 on top of the hardware 3404 and corresponds to the application 3402.

Hardware 3404 may be implemented in a standalone network node with generic or specific components. Hardware 3404 may implement some functions via virtualization. Alternatively, hardware 3404 may be part of a larger cluster of hardware (e.g. such as in a data center or CPE) where many hardware nodes work together and are managed via management and orchestration 3410, which, among others, oversees lifecycle management of applications 3402. In some embodiments, hardware 3404 is coupled to one or more radio units that each include one or more transmitters and one or more receivers that may be coupled to one or more antennas. Radio units may communicate directly with other hardware nodes via one or more appropriate network interfaces and may be used in combination with the virtual components to provide a virtual node with radio capabilities, such as a radio access node or a base station. In some embodiments, some signalling can be provided with the use of a control system 3412 which may alternatively be used for communication between hardware nodes and radio units.

Although the computing devices described herein (e.g. UEs, network nodes) may include the illustrated combination of hardware components, other embodiments may comprise computing devices with different combinations of components. It is to be understood that these computing devices may comprise any suitable combination of hardware and/or software needed to perform the tasks, features, functions and methods disclosed herein. Determining, calculating, obtaining or similar operations described herein may be performed by processing circuitry, which may process information by, for example, converting the obtained information into other information, comparing the obtained information or converted information to information stored in the network node, and/or performing one or more operations based on the obtained information or converted information, and as a result of said processing making a determination. Moreover, while components are depicted as single boxes located within a larger box, or nested within multiple boxes, in practice, computing devices may comprise multiple different physical components that make up a single illustrated component, and functionality may be partitioned between separate components. For example, a communication interface may be configured to include any of the components described herein, and/or the functionality of the components may be partitioned between the processing circuitry and the communication interface. In another example, non-computationally intensive functions of any of such components may be implemented in software or firmware and computationally intensive functions may be implemented in hardware.

In certain embodiments, some or all of the functionality described herein may be provided by processing circuitry executing instructions stored on in memory, which in certain embodiments may be a computer program product in the form of a non-transitory computer-readable storage medium. In alternative embodiments, some or all of the functionality may be provided by the processing circuitry without executing instructions stored on a separate or discrete device-readable storage medium, such as in a hard-wired manner. In any of those particular embodiments, whether executing instructions stored on a non-transitory computer-readable storage medium or not, the processing circuitry can be configured to perform the described functionality. The benefits provided by such functionality are not limited to the processing circuitry alone or to other components of the computing device, but are enjoyed by the computing device as a whole, and/or by end users and a wireless network generally.

The foregoing merely illustrates the principles of the disclosure. Various modifications and alterations to the described embodiments will be apparent to those skilled in the art in view of the teachings herein. It will thus be appreciated that those skilled in the art will be able to devise numerous systems, arrangements, and procedures that, although not explicitly shown or described herein, embody the principles of the disclosure and can be thus within the scope of the disclosure. Various exemplary embodiments can be used together with one another, as well as interchangeably therewith, as should be understood by those having ordinary skill in the art.

### REFERENCES

[1] 3GPP TS 38.214 “Physical layer procedures for data (Release 16)”.
[2] Zhilin Lu, Xudong Zhang, Hongyi He, Jintao Wang, and Jian Song, “Binarized Aggregated Network with Quantization: Flexible Deep Learning Deployment for CSI Feedback in MassiveMIMO System”, arXiv, 2105.00354 v1, May 2021.
[3] RP-213599, “Study on Artificial Intelligence (AI)/Machine Learning (ML) for NR Air Interface”, December 2021.
[4] RWS-210024, “Rel.18 Network AI/ML,” QUALCOMM, TSG RAN Rel-18 workshop, June 28-Jul. 2, 2021.
[5] R1-2208728, “Discussions on AI-CSI”, Ericsson, RAN1 110bis-e, October 2022.
[6] R1-2208908, “Discussion on general aspects of AI/ML framework”, Ericsson, RAN1 110bis-e, October 2022.
[7] “RAN1 Chair's notes” (version 17), RAN1 110bis-e, October 2022

1.-64. (canceled)

65. A method performed by a user equipment, UE, the method comprising:
using an encoder of an autoencoder to compress multiple input multiple output, MIMO, channel state information, CSI, for a channel between the UE and a base station;
forming a CSI report using a mapping between quantized bits representing the compressed MIMO CSI and layers of the channel, wherein the mapping is dependent on an estimated rank for the channel and/or a layer order; and
sending, to the base station, the CSI report and a rank indication for the estimated rank.

66. The method of claim 65, wherein the mapping is defined in a 3rd Generation Partnership Project, 3GPP, Standard Specification.

67. The method of claim 65, wherein the method further comprises:
receiving, from the base station, a mapping indication comprising an indication of the mapping to use to form the CSI report.

68. The method of claim 67, wherein the mapping indication is a suggested mapping option, and wherein the method further comprises:
determining a mapping to use to form the CSI report from the suggested mapping option and at least one other mapping option.

69. The method of claim 67, wherein the mapping indication is an enforced mapping that UE is required to use.

70. The method of claim 65, wherein the method further comprises:
sending, to the base station, a mapping indication comprising an indication of the mapping used to form the CSI report.

71. The method of claim 65, wherein the CSI report comprises the quantized bits concatenated across all layers of the channel according to the layer order.

72. The method of claim 65, wherein the quantized bits are output by the encoder of the autoencoder at the UE.

73. The method of claim 65, wherein compressed MIMO CSI is output by the encoder of the autoencoder at the UE and the method further comprises:
prior to forming the CSI report, quantizing the compressed MIMO CSI.

74. The method of claim 65, wherein compressed MIMO CSI are output by the autoencoder at the UE and the method further comprises:
prior to forming the CSI report, quantizing a subset of the output compressed MIMO CSI corresponding to selected neurons of the encoder of the autoencoder.

75. The method of claim 65, wherein the method further comprises:
determining the CSI based on the received downlink reference signals.

76. The method of claim 65, wherein the method further comprises:
determining the rank indication based on the MIMO CSI.

77. The method of claim 65, wherein the method further comprises:
receiving, from the base station, a quantization indication comprising an indication of a maximum number, Q_B, of quantized bits per neuron of the autoencoder output to be used for determining the CSI report.

78. The method of claim 65, wherein the method further comprises:
transmitting, to the base station, a quantization indication comprising an indication of a maximum number, Q_B, of quantized bits per neuron of the output of the encoder of the autoencoder to be used for determining the CSI report.

79. The method of claim 65, wherein the mapping indicates a number of quantized bits per neuron of the output of the encoder of the autoencoder as a function of channel layer based on the layer order.

80. The method of claim 65, wherein the mapping indicates a number of quantized bits per neuron of the output of the encoder of the autoencoder as a function of the estimated rank for the channel.

81. The method of claim 80, wherein the number of quantized bits per neuron of the output of the encoder of the autoencoder decreases with increasing rank.

82. A method performed by a base station using multi-user multiple input multiple output, MIMO, the method comprising:
receiving, from a user equipment, UE, a channel state information, CSI, report comprising quantized bits representing compressed MIMO CSI for a channel between the UE and the base station, and a rank indication for the channel; and
using a decoder of an autoencoder to decompress the compressed MIMO CSI based on (i) the rank indication and (ii) a mapping between quantized bits representing the compressed MIMO CSI and layers of the channel, wherein the mapping is dependent on an estimated rank for the channel and/or a layer order.

83. A user equipment, UE, comprising a processor and a memory, said memory containing instructions executable by said processor whereby said UE is operative to perform the method of claim 65.

84. A base station comprising a processor and a memory, said memory containing instructions executable by said processor whereby said base station is operative to perform the method of claim 82.
